(19) United States
(12) Patent Application Publication
(10) Pub. No.: US 2026/0223404 A1
(43) Pub. Date: Jul. 30, 2026

(54) THIN-FILM TRANSISTOR, DISPLAY DEVICE, AND METHOD FOR MANUFACTURING DISPLAY DEVICE

(71) Applicant: Sharp Display Technology Corporation, Kameyama City, Mie (JP)

(72) Inventor: Masahito SANO, Kameyama City (JP)

(21) Appl. No.: 19/146,953

(22) PCT Filed: Jan. 16, 2023
(86) PCT No.: PCT/JP2023/000943

§ 371 Date: Jul. 10, 2025

(51) Int. Cl. H10D 30/67; H10D 86/40; H10D 86/60; H10K 59/12; H10K 59/121

(52) U.S. Cl. CPC H10D 30/6737; H10D 30/6731; H10D 30/6755; H10D 86/423; H10D 86/60; H10K 59/1201; H10K 59/1213

(57) ABSTRACT

A thin film transistor includes a pair of terminal electrodes provided at positions spaced apart from each other, a semiconductor layer provided so as to partially overlap each of the pair of terminal electrodes, a gate insulating film provided on the semiconductor layer, and a gate electrode provided so as to overlap the semiconductor layer with the gate insulating film interposed therebetween. An outer edge portion of each terminal electrode is formed into a tapered inclined surface. In each terminal electrode, an inclined surface portion on which the semiconductor layer is formed forms a recessed portion recessed outward in a channel length direction in a plan view.

### TECHNICAL FIELD

The disclosure relates to a thin film transistor, a display device, and a method of manufacturing the display device.

### BACKGROUND ART

In the related art, thin film transistors (hereinafter referred to as TFTs) have been widely used in various display devices such as liquid crystal display devices and organic ElectroLuminescence (hereinafter referred to as EL) display devices, and electronic devices such as Radio Frequency Identification (RFID) and memory devices. A well-known type of TFT is a top gate TFT with a bottom contact structure.

The top gate TFT with a bottom contact structure includes a pair of terminal electrodes, a semiconductor layer, a gate insulating film, and a gate electrode. The pair of terminal electrodes are provided at positions spaced apart from each other and are in contact with a lower surface of the semiconductor layer. The semiconductor layer is provided between the pair of terminal electrodes so as to overlap partially both of the terminal electrodes. The gate electrode overlaps a portion of the semiconductor layer between the pair of terminal electrodes with the gate insulating film interposed therebetween.

Such a thin film transistor is disclosed in, for example, WO 2021/240584.

### SUMMARY

### Technical Problem

In fabricating a top gate TFT with a bottom contact structure, when a pair of terminal electrodes are formed by patterning a common metal film, the pair of terminal electrodes may be connected due to a film residue of the metal film. When this happens, leakage occurs between the two terminal electrodes, so a rework step is performed in which etching is performed using a resist with a pattern that is slightly larger than a resist used for patterning the terminal electrodes, to remove the film residue.

In this rework step, when misalignment occurs in a resist formation position, an inclined surface portion of an outer edge portion of the terminal electrode on which the semiconductor layer is formed may be etched, causing an inclined surface state of the deposited portion to become steeper and deteriorate. When this happens, the semiconductor layer may become extremely thin or discontinued at the inclined surface portion of the terminal electrode where the semiconductor layer is formed, resulting in a connection failure between the terminal electrode and the semiconductor layer.

An object of the disclosure is to suppress occurrence of a connection failure between a terminal electrode and a semiconductor layer in a top gate TFT with a bottom contact structure.

### Solution to Problem

The disclosure applies to a TFT. The TFT according to the disclosure includes a pair of terminal electrodes provided at positions spaced apart from each other, a semiconductor layer partially overlapping each of the pair of terminal electrodes, a gate insulating film provided on the semiconductor layer, and a gate electrode overlapping the semiconductor layer with the gate insulating film interposed between the gate electrode and the semiconductor layer. An outer edge portion of each of the pair of terminal electrodes is formed into a tapered inclined surface. In at least one of the pair of terminal electrodes, an inclined surface portion on which the semiconductor layer is formed forms a recessed portion recessed outward in a channel length direction in a plan view. Alternatively, in at least one of the pair of terminal electrodes, an inclined surface portion on which the semiconductor layer is formed forms a protruding portion protruding inward in the channel length direction in a plan view.

The disclosure also applies to a display device. The display device according to the disclosure includes the TFT described above according to the disclosure.

The disclosure also applies to a method of manufacturing a display device. According to the disclosure, a method of manufacturing a display device includes forming a pair of terminal electrodes at positions spaced apart from each other by depositing a conductive film on a substrate and forming a first resist on the conductive film at locations where the pair of terminal electrodes are to be formed, and then patterning the conductive film by etching using the first resist as a mask, and removing the first resist, after forming a second resist covering the pair of terminal electrodes and removing a film residue of the conductive film by etching using the second resist as a mask, removing the second resist, forming a semiconductor layer partially overlapping both the pair of terminal electrodes, forming a gate insulating film on the semiconductor layer, and forming a gate electrode on the gate insulating film, in which the display device includes multiple thin film transistors, each of the multiple TFTs including the pair of terminal electrodes, the semiconductor layer, the gate insulating film, and the gate electrode. In the forming a pair of terminal electrodes, an outer edge portion of each of the pair of terminal electrodes is formed into a tapered inclined surface, and at least one of the pair of terminal electrodes is formed in a shape in which an inclined surface portion on which the semiconductor layer is formed forms a recessed portion recessed outward in a channel length direction or a protruding portion protruding inward in the channel length direction in a plan view.

### Advantageous Effects of Disclosure

According to the technique of the disclosure, in a top gate TFT with a bottom contact structure, occurrence of a connection failure between a terminal electrode and a semiconductor layer can be suppressed.

### BRIEF DESCRIPTION OF DRAWINGS

FIG. 1 is a plan view illustrating a schematic configuration of an organic EL display device according to a first embodiment.

FIG. 2 is a cross-sectional view taken along line II-II in FIG. 1.

FIG. 3 is a plan view illustrating pixels constituting a display region of the organic EL display device and various wiring lines.

FIG. 4 is a cross-sectional view taken along line IV-IV in FIG. 3.

FIG. 5 illustrates configuration diagrams of a second TFT according to the first embodiment, in which an upper diagram illustrates a plan view, a middle diagram illustrates a cross-sectional view taken along line A-A in the upper diagram, and a lower diagram illustrates a cross-sectional view taken along line B-B in the upper diagram.

FIG. 6 illustrates schematic views illustrating a state in which a third terminal electrode and a fourth terminal electrode are formed in fabrication of the second TFT according to the first embodiment, in which an upper diagram illustrates a plan view, a middle diagram illustrates a cross-sectional view taken along line C-C in the upper diagram, and a lower diagram illustrates a cross-sectional view taken along line D-D.

FIG. 7 illustrates cross-sectional views illustrating a process of forming the third terminal electrode and the fourth terminal electrode in the fabrication of the second TFT according to the first embodiment.

FIG. 8 is a plan view illustrating a second resist formed as a mask in a rework step according to the first embodiment.

FIG. 9 illustrates schematic views illustrating a state in which a film residue occurs between the third terminal electrode and the fourth terminal electrode in the fabrication of the second TFT according to the first embodiment, in which an upper diagram illustrates a plan view and a lower diagram illustrates a cross-sectional view taken along line E-E in the upper diagram.

FIG. 10 illustrates schematic views illustrating a state in which the film residue is removed in the rework step according to the first embodiment, in which an upper diagram illustrates a plan view of a state in which the second resist is formed, and a lower diagram illustrates a plan view of a state in which dry etching is performed.

FIG. 11 illustrates schematic views illustrating a state in which the film residue is removed in the rework step according to the first embodiment, in which an upper diagram illustrates a cross-sectional view taken along line F-F in the upper diagram in FIG. 10, and a lower diagram illustrates a cross-sectional view taken along line G-G in the lower diagram in FIG. 10.

FIG. 12 illustrates schematic views illustrating a state in which a second semiconductor layer is formed in the fabrication of the second TFT according to the first embodiment, in which an upper diagram illustrates a plan view, a middle diagram illustrates a cross-sectional view taken along line H-H in the upper diagram, and a lower diagram illustrates a cross-sectional view taken along line I-I in the upper diagram.

FIG. 13 illustrates schematic views illustrating a state in which a first insulating film and a second metal film are deposited in the fabrication of the second TFT according to the first embodiment, in which an upper diagram illustrates a plan view, a middle diagram illustrates a cross-sectional view taken along line J-J, and a lower diagram illustrates a cross-sectional view taken along line K-K.

FIG. 14 illustrates schematic views illustrating a state in which a second gate insulating film and a second gate electrode are formed in the fabrication of the second TFT according to the first embodiment, in which an upper diagram illustrates a plan view, a middle diagram illustrates a cross-sectional view taken along line L-L in the upper diagram, and a lower diagram illustrates a cross-sectional view taken along line M-M in the upper diagram.

FIG. 15 is a cross-sectional view illustrating a state in which a hydrogen plasma treatment is performed in the fabrication of the second TFT according to the first embodiment.

FIG. 16 illustrates schematic views illustrating a state in which a formation position of the second resist used as a mask in the rework step according to the first embodiment is shifted in a channel length direction, in which an upper diagram illustrates a plan view, a middle diagram illustrates a cross-sectional view taken along line N-N in the upper diagram, and a lower diagram illustrates a cross-sectional view taken along line O-O in the upper diagram.

FIG. 17 illustrates schematic views illustrating a state in which after the rework step according to the first embodiment is performed using the misaligned second resist, a second semiconductor layer is formed, in which an upper diagram illustrates a plan view, a middle diagram illustrates a cross-sectional view taken along line P-P in the upper diagram, and the lower diagram illustrates a cross-sectional view taken along line Q-Q in the upper diagram.

FIG. 18 illustrates schematic views illustrating a state in which the formation position of the second resist is shifted in both the channel length direction and a channel width direction in the rework step according to the first embodiment, in which an upper diagram illustrates a plan view illustrating a state in which the rework step is performed, and a lower diagram illustrates a plan view of a state in which the second semiconductor layer is formed.

FIG. 19 illustrates schematic views illustrating a state in which the formation position of the second resist is shifted in both the channel length direction and the channel width direction in the rework step according to the first embodiment, in which an upper diagram illustrates a plan view illustrating a state in which the rework step is performed, and a lower diagram illustrates a plan view of a state in which the second semiconductor layer is formed.

FIG. 20 is a plan view illustrating the second resist formed as a mask in the rework step according to a modified example.

FIG. 21 illustrates schematic views illustrating a state in which the formation position of the second resist is shifted in the channel length direction in the rework step according to the modified example, in which an upper diagram illustrates a plan view of a state in which the rework step is performed, and a lower diagram illustrates a plan view of a state in which the second semiconductor layer is formed.

FIG. 22 illustrates schematic views illustrating a state in which the formation position of the second resist is shifted in both the channel length direction and the channel width direction in the rework step according to the modified example, in which an upper diagram illustrates a plan view of a state in which the rework step is performed, and a lower diagram illustrates a plan view of a state in which the second semiconductor layer is formed.

FIG. 23 illustrates schematic views illustrating a state in which the formation position of the second resist is shifted in both the channel length direction and the channel width direction in the rework step according to the modified example, in which an upper diagram illustrates a plan view of a state in which the rework step is performed, and a lower diagram illustrates a plan view of a state in which the second semiconductor layer is formed.

FIG. 24 illustrates configuration diagrams of a second TFT according to a second embodiment, in which an upper diagram illustrates a plan view, a middle diagram illustrates a cross-sectional view taken along line R-R in the upper diagram, and a lower diagram illustrates a cross-sectional view taken along line S-S in the upper diagram.

FIG. 25 is a plan view illustrating a second resist formed as a mask in a rework step according to the second embodiment.

FIG. 26 illustrates schematic views illustrating a state in which a formation position of the second resist is shifted in a channel length direction in the rework step according to the second embodiment, in which an upper diagram illustrates a plan view of a state in which the rework step is performed, and a lower diagram illustrates a plan view of a state in which a second semiconductor layer is formed.

FIG. 27 illustrates schematic views illustrating a state in which the formation position of the second resist is shifted in both the channel length direction and a channel width direction in the rework step according to the second embodiment, in which an upper diagram illustrates a plan view of a state in which the rework step is performed, and a lower diagram illustrates a plan view of a state in which the second semiconductor layer is formed.

FIG. 28 illustrates schematic views illustrating a state in which the formation position of the second resist is shifted in both the channel length direction and the channel width direction in the rework step according to the second embodiment, in which an upper diagram illustrates a plan view of a state in which the rework step is performed, and a lower diagram illustrates a plan view of a state in which the second semiconductor layer is formed.

FIG. 29 is a plan view illustrating a configuration of a second TFT according to a third embodiment.

FIG. 30 is a plan view illustrating a second resist formed as a mask in a rework step according to the third embodiment.

FIG. 31 illustrates schematic views illustrating a state in which a formation position of the second resist is shifted in a channel length direction in the rework step according to the third embodiment, in which an upper diagram illustrates a plan view of a state in which the rework step is performed, and a lower diagram illustrates a plan view of a state in which a second semiconductor layer is formed.

FIG. 32 illustrates schematic views illustrating a state in which the formation position of the second resist is shifted in both the channel length direction and a channel width direction in the rework step according to the third embodiment, in which an upper diagram illustrates a plan view of a state in which the rework step is performed, and a lower diagram illustrates a plan view of a state in which the second semiconductor layer is formed.

FIG. 33 illustrates schematic views illustrating a state in which the formation position of the second resist is shifted in both the channel length direction and the channel width direction in the rework step according to the third embodiment, in which an upper diagram illustrates a plan view of a state in which the rework step is performed, and a lower diagram illustrates a plan view of a state in which the second semiconductor layer is formed.

FIG. 34 is a plan view illustrating a configuration of a second TFT according to a comparative example.

FIG. 35 illustrates schematic views illustrating a state in which a formation position of a second resist is shifted in a channel length direction in a rework step according to the comparative example, in which an upper diagram illustrates a plan view of a state in which the rework step is performed, and a lower diagram illustrates a cross-sectional view taken along line T-T in the upper diagram.

FIG. 36 illustrates schematic views illustrating a state in which after the rework step according to the comparative example is performed using the misaligned second resist, a second semiconductor layer is formed, in which an upper diagram illustrates a plan view and a lower diagram illustrates a cross-sectional view taken along line U-U in the upper diagram.

### DESCRIPTION OF EMBODIMENTS

Exemplary embodiments will be described below in detail with reference to the drawings. In the embodiments described below, an organic EL display device is described as an example of a display device according to the disclosure. Note that the drawings are for schematically describing the techniques of the disclosure. Thus, in the drawings, the dimensions, ratios, or numbers may be exaggerated or simplified to facilitate the techniques of the disclosure.

In the following embodiments, a “first direction” means a horizontal direction of a screen when a display device is oriented in a specified state of use. A “second direction” is a direction orthogonal to the first direction and means a vertical direction of the screen when the display device is oriented in a specified state of use. A row of constituent elements such as subpixels means a horizontal arrangement of multiple constituent elements forming a line in the first direction. A column of constituent elements such as subpixels means a vertical arrangement of multiple constituent elements forming a line in the second direction.

In the following embodiments, the description that, on a constituent element such as a certain film, layer or element, a constituent element such as another film, layer or element is provided or formed means not only a case where another constituent element is present immediately above the certain constituent element but also a case where a constituent element such as still another film, layer, or element is interposed between both of the constituent elements.

In the following embodiments, the description that a certain constituent element is connected to another constituent element means that the constituent elements are electrically connected unless otherwise specified. This description means, within the scope of the gist of the technique of the disclosure, not only a case where the constituent elements are directly connected but also a case where the constituent elements are indirectly connected with still another constituent element interposed therebetween. The description also includes a case where a certain constituent element is integrated with another constituent element, that is, a part of the certain constituent element constitutes the other constituent element.

In the following embodiments, a description that a certain constituent element is in the same layer as another constituent element means that the certain constituent element is formed in the same process as the other constituent element. A description that a certain constituent element is in a lower layer below another constituent element means that the certain constituent element is deposited in a process earlier than the other constituent element or is formed from a film deposited in an earlier process. A description that a certain constituent element is in an upper layer above another constituent element means that the certain constituent element is deposited in a process later than the other constituent element or is formed from a film deposited in a later process.

In the following embodiments, the description that a certain constituent element is the same as or equivalent to another constituent element includes not only a state where the certain constituent element is completely the same as or completely equivalent to the other constituent element, but also a state where the certain constituent element is substantially the same as or substantially equivalent to the other constituent element, such as a state where the certain constituent element and the other constituent element vary within a range of a manufacturing variation, tolerance, or the like.

In the following embodiments, the descriptions of first, second, third, . . . are used to distinguish the words and phrases to which these descriptions are given, and no limitation with regard to the number and order of the words and phrases is intended.

### First Embodiment

An organic EL display device 1 according to this embodiment is used as a display for mobile devices such as multi-functional telephones called smartphones and tablet terminals. The organic EL display device 1 may also be used as a display for various other devices such as personal computers (PCs) and television sets.

### Schematic Configuration of Organic EL Display Device

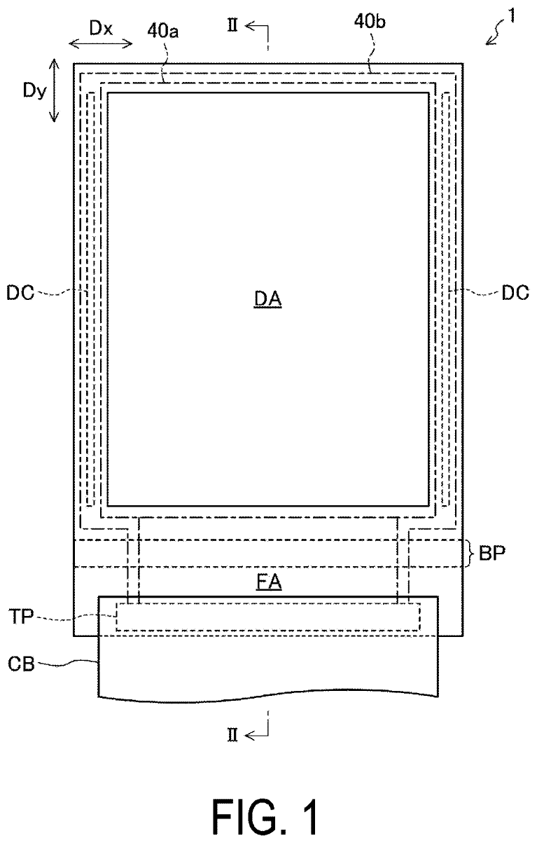

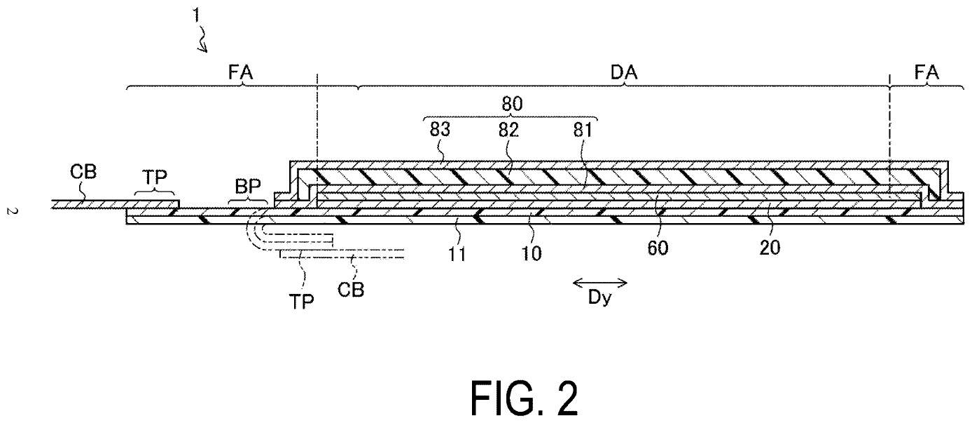

The organic EL display device 1 is a display device that uses organic electroluminescence elements (organic EL elements) 65. The organic EL display device 1 includes TFTs 50 and employs an active matrix driving method. As illustrated in FIGS. 1 and 2, the organic EL display device 1 has a display region DA and a frame region FA.

The display region DA is a region in which an image is displayed and constitutes a screen. The display region DA is provided in a rectangular shape, for example. The display region DA may have a substantially rectangular shape such as a shape in which at least one side is arc-shaped, a shape in which at least one corner is arc-shaped or a shape in which a cutout portion is formed in at least one side or may have any other shape.

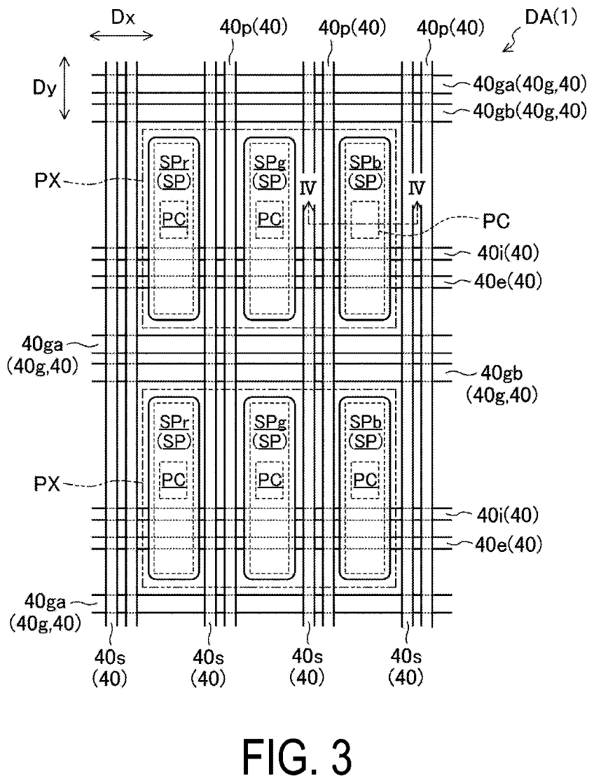

As illustrated in FIG. 3, the display region DA includes multiple pixels PX. The multiple pixels PX are arrayed in a matrix shape. Each pixel PX is constituted by three subpixels SP. The three subpixels SP are a subpixel SPr for emitting red light, a subpixel SPg for emitting green light, and a subpixel SPb for emitting blue light.

These three subpixels SPr, SPg, and SPb are arrayed, for example, in a stripe pattern. Each of the subpixels SPr, SPg, and SPb is formed of the organic EL element 65. A pixel circuit PC is provided in each subpixel SP. Each pixel circuit PC controls light emission of a corresponding subpixel SP (organic EL element 65).

The frame region FA is a region that constitutes a non-display region other than the screen. As illustrated in FIGS. 1 and 2, the frame region FA is provided around the display region DA, for example, in a rectangular frame-like shape. The frame region FA may be in a frame shape other than a rectangle. The frame region FA includes a terminal portion TP and a bending portion BP.

The terminal portion TP is a portion for connecting to an external circuit. The terminal portion TP is provided at a position near an outer edge of a portion constituting one side of the frame region FA and extends along that side in a first direction Dx. Although not illustrated, the terminal portion TP includes multiple terminals. To the terminal portion TP, a wiring board CB such as a Flexible Printed Circuit (FPC) is connected.

The bending portion BP is provided between the terminal portion TP and the display region DA and extends horizontally over the entire frame region FA in the first direction Dx. The frame region FA can be bent at the bending portion BP, for example, by about 180° so as to form a U-shape (indicated by two-dot chain lines in FIG. 2). Thus, the terminal portion TP is disposed on the back face side of the organic EL display device 1.

Drive circuits DC are provided in the frame region FA. In the frame region FA, the drive circuits DC are each disposed in a portion constituting a side (a left or right side in FIG. 1) adjacent to a side where the terminal portion TP is provided. The drive circuit DC is monolithically formed as a part of a TFT layer 20 which will be described later. The drive circuit DC includes a gate driver and an emission driver.

In the frame region FA, a first frame line 40a and a second frame line 40b are provided. The first frame line 40a and the second frame line 40b are both power supply trunk lines that are formed to surround the display region DA and extend to the terminal portion TP. A high-level power supply voltage (ELVDD) is supplied to the first frame line 40a via the wiring board CB. A low-level power supply voltage (ELVSS) is supplied to the second frame line 40b via the wiring board CB.

### Layered Structure of Organic EL Display Device

As illustrated in FIG. 2, the organic EL display device 1 includes a substrate layer 10, the Thin Film Transistor layer (TFT layer) 20, a light-emitting element layer 60, and a sealing film 80.

### Substrate Layer

The substrate layer 10 is a layer forming a base of the organic EL display device 1. The substrate layer 10 is an example of a substrate. The substrate layer 10 has flexibility. The substrate layer 10 is formed of an organic resin material such as a polyimide resin, a polyamide resin, or an epoxy resin. A protection film 11 having optical transparency is bonded to the back face of the substrate layer 10.

### TFT Layer

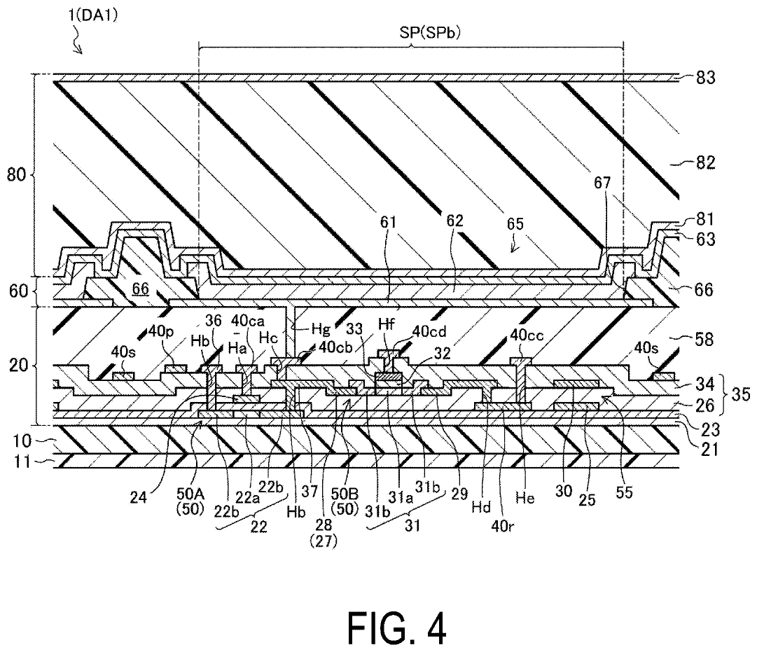

The TFT layer 20 is provided on the substrate layer 10. The TFT layer 20 includes various wiring lines 40, multiple pixel circuits PC, and a flattening film 58. The various wiring lines 40, the pixel circuits PC, and the flattening film 58 are provided above a base coat film 21 illustrated in FIG. 4. The base coat film 21 is provided over the substantially entire surface of the substrate layer 10.

The various wiring lines 40 include multiple gate lines 40g, multiple light emission control lines 40e, multiple initialization lines 40i, multiple power source lines 40p, and multiple source lines 40s, as illustrated in FIG. 3. The gate lines 40g, the light emission control lines 40e, the initialization lines 40i, the power source lines 40p, and the source lines 40s are provided in the display region DA.

Each of the multiple gate lines 40g is a wiring line that transmits a gate signal to the pixel circuit PC. The multiple gate lines 40g are spaced apart from each other in a second direction Dy and extend parallel to each other in the first direction Dx. The gate lines 40g include a first gate line 40ga and a second gate line 40gb.

The first gate line 40ga is used to control an N-channel TFT 50. The second gate line 40gb is used to control a P-channel TFT 50. The first gate line 40ga and the second gate line 40gb are provided for each row of the subpixels SP. Each first gate line 40ga and each second gate line 40gb are drawn out to the frame region FA and connected to the gate driver of the drive circuit DC.

Each of the multiple light emission control lines 40e is a wiring line that transmits an emission signal to the pixel circuit PC. The multiple light emission control lines 40e are spaced apart from each other in the second direction Dy and extend parallel to each other in the first direction Dx. The light emission control line 40e is provided for each row of the subpixels SP. Each light emission control line 40e is drawn out to the frame region FA and connected to the emission driver of the drive circuit DC.

The multiple initialization lines 40i are wiring lines that apply initialization voltages to the pixel circuits PC. The multiple initialization lines 40i are spaced apart from each other in the second direction Dy and extend parallel to each other in the first direction Dx. The initialization line 40i is provided for each row of the subpixels SP. Each initialization line 40i is drawn out to the frame region FA and connected to the drive circuit DC or the second frame line 40b.

Each of the multiple power source lines 40p is a wiring line that applies a predetermined high-level power supply voltage (ELVDD) to the pixel circuit PC. The multiple power source lines 40p are spaced apart from each other in the first direction Dx and extend parallel to each other in the second direction Dy. The power source line 40p is provided for each column of the subpixels SP. Each power source line 40p is drawn out to the frame region FA and connected to the first frame line 40a.

Each of the multiple source lines 40s is a wiring line that transmits a source signal to the pixel circuit PC. The multiple source lines 40s are spaced apart from each other in the first direction Dx and extend parallel to each other in the second direction Dy. The source line 40s is provided for each column of the subpixels SP. Each source line 40s is drawn out to the terminal portion TP and connected to a display control circuit (source driver) via the wiring board CB.

The first gate lines 40ga, the light emission control lines 40e, and the initialization lines 40i are formed of the same material in the same layer as first gate electrodes 24, first capacitance electrodes 25, and relay lines 40r. The second gate lines 40gb are formed of the same material in the same layer as second gate electrodes 33. The power source lines 40p and the source lines 40s are formed of the same material in the same layer as first terminal electrodes 36, second terminal electrodes 37, and first to fourth connection lines 40ca, 40cb, 40cc, and 40cd.

The pixel circuit PC operates based on a gate signal, an emission signal, an initialization voltage, and a high-level power supply voltage (ELVDD) supplied through the first gate line 40ga, the second gate line 40gb, the light emission control line 40e, the initialization line 40i, and the power source line 40p. In each frame, the pixel circuit PC resets a charge stored in a pixel electrode 61, and then supplies a drive current corresponding to the source signal to the organic EL element 65.

The pixel circuit PC includes multiple TFTs 50 and a capacitor 55. The multiple TFTs 50 and the capacitor 55 constituting the pixel circuit PC are provided corresponding to each of the multiple subpixels SP. The multiple TFTs 50 include a first TFT 50A and a second TFT 50B. That is, the first TFT 50A and the second TFT 50B constitute the pixel circuit PC. The second TFT 50B corresponds to a Thin Film Transistor (TFT) according to the technique of the disclosure.

The first TFT 50A is configured as a top gate type with a top contact structure. The multiple first TFTs 50A are included in the pixel circuit PC. The first TFT 50A includes a first semiconductor layer 22, a first gate insulating film 23, the first gate electrode 24, an interlayer insulating film 35, the first terminal electrode 36, and the second terminal electrode 37.

The first semiconductor layer 22 is provided in an island shape on the base coat film 21 and is individually separated for each first TFT 50A. The first semiconductor layer 22 may be provided continuously across the multiple first TFTs 50A. The first semiconductor layer 22 includes a channel region 22a and a pair of conductive regions 22b. The channel region 22a is provided between the pair of conductive regions 22b. The pair of conductive regions 22b are provided separate from each other with the channel region 22a interposed therebetween.

The first gate insulating film 23 covers the multiple first semiconductor layers 22 and is provided continuously across the multiple first TFTs 50A. The first gate insulating film 23 may be provided in an island shape on each first semiconductor layer 22 and may be individually separated for each first TFT 50A. The first gate electrode 24 is provided on the first gate insulating film 23. The first gate electrode 24 overlaps the channel region 22a of the first semiconductor layer 22 with the first gate insulating film 23 interposed therebetween.

The interlayer insulating film 35 is formed by layering a first interlayer insulating film 26 and a second interlayer insulating film 34 in this order on the first gate insulating film 23. The interlayer insulating film 35 is provided so as to cover the multiple first gate electrodes 24. A first contact hole Ha is formed in the interlayer insulating film 35. The first contact hole Ha reaches the first gate electrode 24. The first connection line 40ca is connected to the first gate electrode 24 via the first contact hole Ha.

A pair of second contact holes Hb are formed in the first gate insulating film 23 and the interlayer insulating film 35 for each first TFT 50A. Some of the multiple second contact holes Hb are formed only in the first gate insulating film 23 and the first interlayer insulating film 26. The pair of second contact holes Hb reach corresponding conductive regions 22b of the first semiconductor layer 22 that are different from each other.

The first terminal electrode 36 and the second terminal electrode 37 are provided at positions spaced apart from each other. The first terminal electrode 36 and the second terminal electrode 37 may be each provided on the first interlayer insulating film 26 or the second interlayer insulating film 34. The first terminal electrode 36 and the second terminal electrode 37 are connected to the conductive regions 22b of the first semiconductor layer 22 via different second contact holes Hb.

The second TFT 50B is configured as a top gate type with a bottom contact structure. The multiple second TFTs 50B are included in the pixel circuit PC. The second TFT 50B includes a third terminal electrode 28 and a fourth terminal electrode 29, a second semiconductor layer 31, a second gate insulating film 32, and the second gate electrode 33.

The third terminal electrode 28 and the fourth terminal electrode 29 correspond to a pair of terminal electrodes in the TFT of the disclosure. The second semiconductor layer 31 corresponds to a semiconductor layer in the TFT of the disclosure. The second gate insulating film 32 corresponds to a gate insulating film in the TFT of the disclosure. The second gate electrode 33 corresponds to a gate electrode in the TFT of the disclosure.

The third terminal electrode 28 and the fourth terminal electrode 29 are provided at positions spaced apart from each other on the first interlayer insulating film 26. A third contact hole Hc is formed in the second interlayer insulating film 34 corresponding to one of the second TFTs 50B. The third contact hole Hc reaches a metal layer 27 forming the third terminal electrode 28 or the fourth terminal electrode 29.

The second connection line 40cb provided on the second interlayer insulating film 34 is connected to at least one of the third terminal electrode 28 and the fourth terminal electrode 29 (the third terminal electrode 28 in the example illustrated in FIG. 4) via the third contact hole Hc. At least one of the third terminal electrode 28 and the fourth terminal electrode 29 may be formed integrally with the first terminal electrode 36 or the second terminal electrode 37, and may be connected to the conductive region 22b of the first semiconductor layer 22 via the second contact hole Hb.

A fourth contact hole Hd is formed in the first interlayer insulating film 26, and a fifth contact hole He is formed in the interlayer insulating film 35, corresponding to one of the second TFTs 50B. The fourth contact hole Hd and the fifth contact hole He reach different portions of the relay line 40r provided on the first gate insulating film 23.

At least one of the third terminal electrode 28 and the fourth terminal electrode 29 (the fourth terminal electrode 29 in the example illustrated in FIG. 4) is connected to the relay line 40r via the fourth contact hole Hd. The third terminal electrode 28 and the fourth terminal electrode 29 of one second TFT 50B may be formed continuously with the third terminal electrode 28 and the fourth terminal electrode 29 of another second TFT 50B. The third connection line 40cc provided on the second interlayer insulating film 34 is connected to the relay line 40r via the fifth contact hole He.

The second semiconductor layer 31 is provided in an island shape on the first interlayer insulating film 26 and is individually separated for each second TFT 50B. The second semiconductor layer 31 may be provided continuously across the multiple second TFTs 50B. The second semiconductor layer 31 is provided so as to partially overlap both the third terminal electrode 28 and the fourth terminal electrode 29. The second semiconductor layer 31 includes a channel region 31a and a pair of conductive regions 31b. The channel region 31a is provided between the pair of conductive regions 31b. The pair of conductive regions 31b are provided spaced apart from each other with the channel region 31a interposed therebetween.

The second gate insulating film 32 is provided in an island shape on the second semiconductor layer 31, and is individually separated for each second TFT 50B. The second gate insulating film 32 may cover the multiple second semiconductor layers 31 and may be provided continuously across the multiple second TFTs 50B. The second gate electrode 33 is provided on the second gate insulating film 32.

The second gate electrode 33 overlaps the channel region 31a of the second semiconductor layer 31 with the second gate insulating film 32 interposed therebetween. A sixth contact hole Hf is formed in the second interlayer insulating film 34. The sixth contact hole Hf reaches the second gate electrode 33. The fourth connection line 40cd is connected to the second gate electrode 33 via the sixth contact hole Hf.

The capacitor 55 includes the first capacitance electrode 25, a second capacitance electrode 30, and the first interlayer insulating film 26. The first capacitance electrode 25 is provided on the first gate insulating film 23. The second capacitance electrode 30 is provided on the first interlayer insulating film 26. The first capacitance electrode 25 and the second capacitance electrode 30 overlap each other with the first interlayer insulating film 26 interposed therebetween.

The base coat film 21, the first gate insulating film 23, the first interlayer insulating film 26, the second gate insulating film 32, and the second interlayer insulating film 34 are made of an inorganic insulating material such as silicon oxide, silicon nitride, or silicon oxynitride. Each of these various inorganic insulating films may be composed of a single layer film or a layered film.

The third terminal electrode 28 and the fourth terminal electrode 29 are made of a metal material containing molybdenum (Mo) or tungsten (W). The other wiring lines and electrodes described above are made of a metal material such as aluminum (Al), tungsten (W), molybdenum (Mo), tantalum (Ta), chromium (Cr), titanium (Ti), or copper (Cu). Those various wiring lines and electrodes may be composed of a single layer film or a layered film.

The first semiconductor layer 22 is formed of polysilicon. The polysilicon forming the first semiconductor layer 22 is, for example, Low Temperature Polycrystalline Silicon (LTPS). The second semiconductor layer 31 is formed of an oxide semiconductor. The oxide semiconductor forming the second semiconductor layer 31 is, for example, an In—Ga—Zn—O based semiconductor.

The In—Ga—Zn—O based semiconductor is ternary oxide of indium (In), gallium (Ga), and zinc (Zn), and a ratio (composition ratio) of In, Ga, and Zn is not limited to any specific value. The In—Ga—Zn—O-based semiconductor may be amorphous or crystalline. The second semiconductor layer may contain other oxide semiconductors in addition to or in place of the In—Ga—Zn—O based semiconductor.

Examples of the other oxide semiconductor may include an In—Sn—Zn—O based semiconductor (for example, In₂O₃—SnO₂-ZnO; InSnZnO). Here, the In—Sn—Zn—O based semiconductor is a ternary oxide of indium (In), tin (Sn), and zinc (Zn).

Further, examples of the other oxide semiconductors may include an In—Al—Zn—O based semiconductor, an In—Al—Sn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), an Mg—Zn—O based semiconductor, and an In—Ga—Sn—O based semiconductor.

Further, examples of the other oxide semiconductors may include an In—Ga—O based semiconductor, a Zr—In—Zn—O based semiconductor, a Hf—In—Zn—O based semiconductor, an Al—Ga—Zn—O based semiconductor, InGaO₃(ZnO)₅, magnesium zinc oxide (MgₓZn₁₋ₓO), and cadmium zinc oxide (CdₓZn₁₋ₓO).

The flattening film 58 is provided on the second interlayer insulating film 34 so as to cover the various wiring lines 40, the multiple TFTs 50, and the multiple capacitors 55 in the display region DA. The flattening film 58 extends over the entire display region DA. A surface of the TFT layer 20 is flattened by the flattening film 58.

A seventh contact hole Hg is formed in the flattening film 58 for each subpixel SP. The seventh contact hole Hg reaches the second connection line 40cb. The flattening film 58 is made of, for example, an organic resin material such as a polyimide resin or an acrylic resin, or a polysiloxane-based Spin On Glass (SOG) material.

### Light-Emitting Element Layer

The light-emitting element layer 60 is provided on the TFT layer 20. As illustrated in FIG. 4, the light-emitting element layer 60 includes the multiple organic ElectroLuminescence elements (organic EL elements) 65 and an edge cover 66. The organic EL element 65 is an example of a light-emitting element. The organic EL element 65 is configured as a top emission type. In the organic EL element 65, light emitted in an organic EL layer 62 is extracted to a sealing film 80 side.

The multiple organic EL elements 65 are provided in the display region DA. To be specific, the organic EL elements 65 are provided corresponding to the multiple subpixels SP, respectively. Each of the multiple organic EL elements 65 constitutes the subpixel SP. Light emission of each organic EL element 65 is controlled by operation of the corresponding pixel circuit PC. Each organic EL element 65 includes the pixel electrode 61, the organic EL layer 62, and a common electrode 63.

The pixel electrodes 61 are provided on the flattening film 58. The pixel electrodes 61 are arrayed in a matrix corresponding to the multiple subpixels SP, respectively. The pixel electrode 61 is connected to a predetermined TFT 50 (in this example, the second TFT 50B) via the seventh contact hole Hg. The pixel electrode 61 functions as an anode electrode, and injects holes into the organic EL layer 62. A conductive material having a large work function is preferably used for the pixel electrode 61.

Examples of the material of the pixel electrode 61 include metals such as silver (Ag), aluminum (Al), nickel (Ni), titanium (Ti), indium (In), and tin (Sn). The material of the pixel electrode 61 may be a metal compound or an alloy. The material of the pixel electrode 61 may be a conductive oxide such as indium tin oxide (ITO) or indium zinc oxide (IZO). The pixel electrode 61 may be composed of a single layer film or a layered film.

The edge cover 66 is provided on the flattening film 58 so as to partition the multiple pixel electrodes 61. The edge cover 66 is formed in a lattice pattern to partition the multiple pixel electrodes 61. The edge cover 66 is located in an upper layer above the pixel electrodes 61, covers outer edges (peripheral edge portions) of the pixel electrodes 61, and has multiple openings 67 that partially expose the pixel electrodes 61. The edge cover 66 is made of, for example, a resin material similar to that of the flattening film 58.

The organic EL layer 62 is provided on each pixel electrode 61 in the opening 67 in the edge cover 66. The organic EL layer 62 includes a hole injection layer, a hole transport layer, a light-emitting layer, an electron transport layer, and an electron injection layer. The hole injection layer, the hole transport layer, the light-emitting layer, the electron transport layer, and the electron injection layer are layered in this order on the pixel electrode 61, and are made of known compounds suitable for the respective functions. The organic EL layer 62 emits light when a current is applied between the pixel electrode 61 and the common electrode 63.

The common electrode 63 is provided continuously over the entire display region DA and is common to the multiple subpixels SP. The common electrode 63 covers the edge cover 66 and the organic EL layers 62 and overlaps the pixel electrodes 61 with the organic EL layers 62 interposed therebetween. The common electrode 63 also extends to the frame region FA and is connected to the second frame line 40b. The common electrode 63 functions as a cathode electrode and injects electrons into the organic EL layer 62. A conductive material having a small work function is preferably used for the common electrode 63.

Examples of the material of the common electrode 63 include an electrically conductive oxide such as Indium Tin Oxide (ITO) and Indium Zinc Oxide (IZO). The material of the common electrode 63 may be a metal such as silver (Ag), aluminum (Al), lithium (Li), magnesium (Mg), calcium (Ca), or ytterbium (Yb). The material of the common electrode 63 may be a metal compound or an alloy. The common electrode 63 may be composed of a single layer film or a layered film.

### Sealing Film

The sealing film 80 is provided on the light-emitting element layer 60. As illustrated in FIG. 4, the sealing film 80 covers and seals the multiple organic EL elements 65 and protects the organic EL elements 65 (particularly, the organic EL layers 62) from moisture, oxygen, and the like. The sealing film 80 is provided over the entire display region DA and extends to the frame region FA. The sealing film 80 includes a first inorganic film 81, an organic film 82, and a second inorganic film 83.

The first inorganic film 81, the organic film 82, and the second inorganic film 83 are provided in this order on the light-emitting element layer 60. The first inorganic film 81 and the second inorganic film 83 extend further toward a peripheral side of the frame region FA than the organic film 82, and overlap each other in an outer portion of the frame region FA. The organic film 82 is enclosed by the first inorganic film 81 and the second inorganic film 83.

The first inorganic film 81 and the second inorganic film 83 are each made of, for example, an inorganic insulating material such as silicon oxide, silicon nitride, or silicon oxynitride. The organic film 82 is made of, for example, an organic resin material such as an acrylic resin, an epoxy resin, a silicone resin, a polyurea resin, a parylene resin, a polyimide resin, or a polyamide resin. The organic film 82 is formed by applying a liquid material (organic insulating material).

### Detailed Configuration of Second TFT

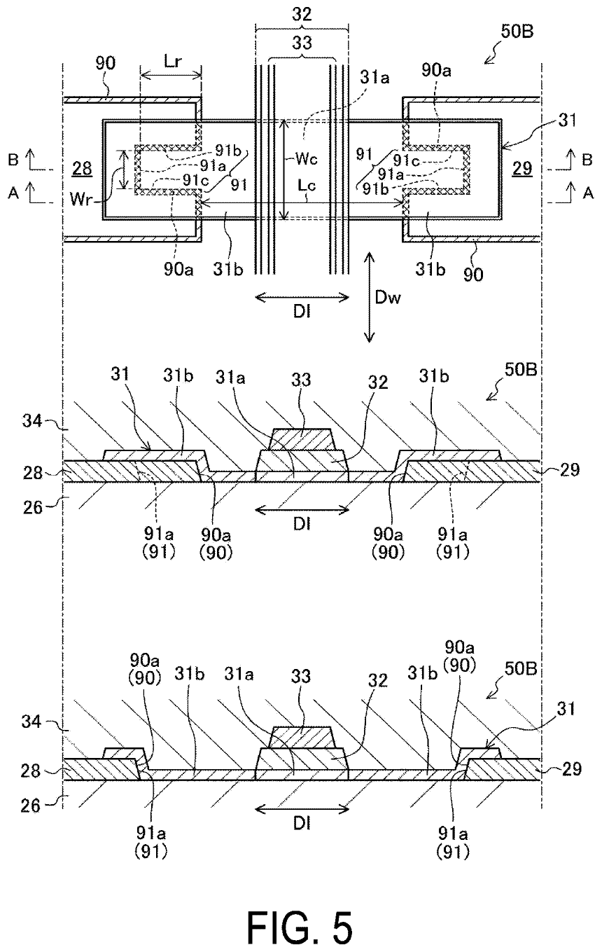

As illustrated in FIG. 5, in the second TFT 50B, an outer edge portion of the third terminal electrode 28 and an outer edge portion of the fourth terminal electrode 29 are each formed into tapered inclined surfaces 90 (portions hatched with diagonal lines in FIG. 5; the same applies to other plan views corresponding to FIG. 5). The inclined surfaces 90 are provided around an entire periphery of the outer edge portion of the third terminal electrode 28 and around an entire periphery of the outer edge portion of the fourth terminal electrode 29. The inclined surface 90 may be provided only on part of the outer edge portion of the third terminal electrode 28, or may be provided only on part of the outer edge portion of the fourth terminal electrode 29.

A channel length Lc and a channel width Wc are set in the second semiconductor layer 31. The channel length Lc corresponds to a distance between the pair of conductive regions 31b and denotes a length of a current path formed in the channel region 31a. The channel width Wc corresponds to a length by which the pair of conductive regions 31b face each other across the channel region 31a and denotes a width of the current path formed in the channel region 31a.

The pair of conductive regions 31b of the second semiconductor layer 31 are located separately on both sides in a direction along the channel length Lc (hereinafter referred to as a channel length direction) Dl. One of the conductive regions 31b is formed on the inclined surface 90 of the third terminal electrode 28 and overlaps a central portion of the third terminal electrode 28 in a direction along the channel width Wc (hereinafter referred to as a channel width direction) Dw. The other conductive region 31b is formed on the inclined surface 90 of the fourth terminal electrode 29 and overlaps a central portion of the fourth terminal electrode 29 in the channel width direction Dw.

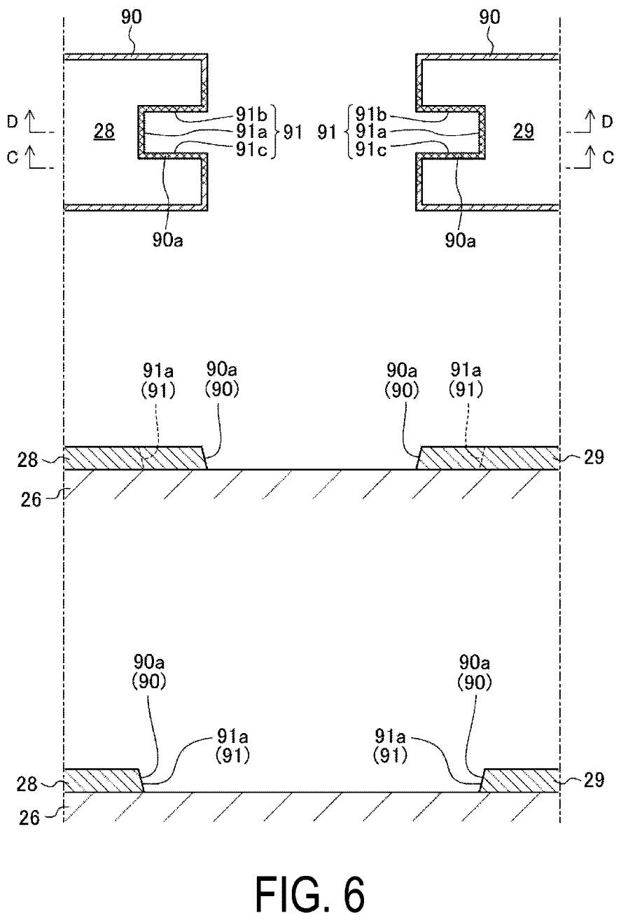

Inclined surface portions 90a of the third terminal electrode 28 and the fourth terminal electrode 29 on which the second semiconductor layer 31 is formed (portions hatched with a grid in FIG. 6; hereinafter referred to as semiconductor layer formable inclined surfaces) face each other with the channel region 31a interposed therebetween in a plan view. The semiconductor layer formable inclined surface 90a of the third terminal electrode 28 and the semiconductor layer formable inclined surface 90a of the fourth terminal electrode 29 form recessed portions 91 recessed outward in the channel length direction Dl in a plan view.

The recessed portion 91 of the third terminal electrode 28 and the recessed portion 91 of the fourth terminal electrode 29 are each formed in a rectangular cutout shape with one side opened toward the channel region 31a. Each recessed portion 91 is composed of a first edge portion 91a, a second edge portion 91b, and a third edge portion 91c. The first edge portion 91a is located at a back side of the recessed portion 91 and is a portion of the recessed portion 91 that faces the channel region 31a in a plan view. The second edge portion 91b and the third edge portion 91c extend from different end portions of the first edge portion 91a toward the channel region 31a in a plan view and are portions of the recessed portion 91 that face each other in the channel width direction Dw.

A length Lr of each recessed portion 91 is, for example, 300 nm or more and 10000 nm or less. A width Wr of each recessed portion 91 is, for example, 1000 nm or more and 20000 nm or less. Here, the length Lr of the recessed portion 91 denotes a dimension of the recessed portion 91 in the channel length direction Dl. The width Wr of the recessed portion 91 is a dimension of the recessed portion 91 in the channel width direction Dw. The length Lr and the width Wr of the recessed portion 91 are equal in the third terminal electrode 28 and the fourth terminal electrode 29. At least one of the length Lr and the width Wr of the recessed portion 91 may be different in the third terminal electrode 28 and the fourth terminal electrode 29.

The one conductive region 31b of the second semiconductor layer 31 extends from the outside of the third terminal electrode 28 (the channel region 31a side) onto the third terminal electrode 28 via the semiconductor layer formable inclined surface 90a. The one conductive region 31b of the second semiconductor layer 31 extends on the semiconductor layer formable inclined surface 90a in at least part of the recessed portion 91 and is formed continuously on the third terminal electrode 28, thereby ensuring connection between the second semiconductor layer 31 and the third terminal electrode 28.

The other conductive region 31b of the second semiconductor layer 31 extends from the outside of the fourth terminal electrode 29 (the channel region 31a side) onto the fourth terminal electrode 29 via the semiconductor layer formable inclined surface 90a. The other conductive region 31b of the second semiconductor layer 31 extends on the semiconductor layer formable inclined surface 90a in at least part of the recessed portion 91 and is formed continuously on the fourth terminal electrode 29, thereby ensuring connection between the second semiconductor layer 31 and the fourth terminal electrode 29.

### Manufacturing Method of Organic EL Display Device

To manufacture the organic EL display device 1, first, the substrate layer 10 is formed by applying an organic resin material onto the surface of a glass substrate and performing baking treatment.

Subsequently, the TFT layer 20, the light-emitting element layer 60, and the sealing film 80 are sequentially formed on the substrate layer 10 using a known film forming method such as a plasma Chemical Vapor Deposition (CVD) technique, sputtering, or a vacuum vapor deposition technique, a known coating method such as a spin coating method or an ink-jet method, and a known patterning technique such as photolithography.

Then, the glass substrate is peeled off from the substrate layer 10 by, for example, irradiating the rear surface of the substrate layer 10 with a laser beam from the glass substrate side. Subsequently, a polarizer or a cover panel is bonded to the surface of the sealing film 80. Further, the protection film 11 is bonded to a back face of the substrate layer 10. Furthermore, the display control circuit is mounted by connecting the wiring board CB to the terminal portion TP.

The organic EL display device 1 can be manufactured in the manner described above.

### Fabrication Method of Second TFT

A step of forming the TFT layer 20 includes a step of fabricating the second TFT 50B. The step of fabricating the second TFT 50B includes a terminal electrode forming step, a rework step, a semiconductor layer forming step, and a gate insulating film and electrode forming step.

The terminal electrode forming step is performed after the first interlayer insulating film 26 is formed in the step of forming the TFT layer 20. In advance, the second contact hole Hb (the hole passing through only the first gate insulating film 23 and the first interlayer insulating film 26) is formed in the first gate insulating film 23 and the first interlayer insulating film 26, and the fourth contact hole Hd is formed in the first interlayer insulating film 26. As illustrated in FIG. 6, in the terminal electrode forming step, the third terminal electrode 28 and the fourth terminal electrode 29 are formed at positions spaced apart from each other on the first interlayer insulating film 26.

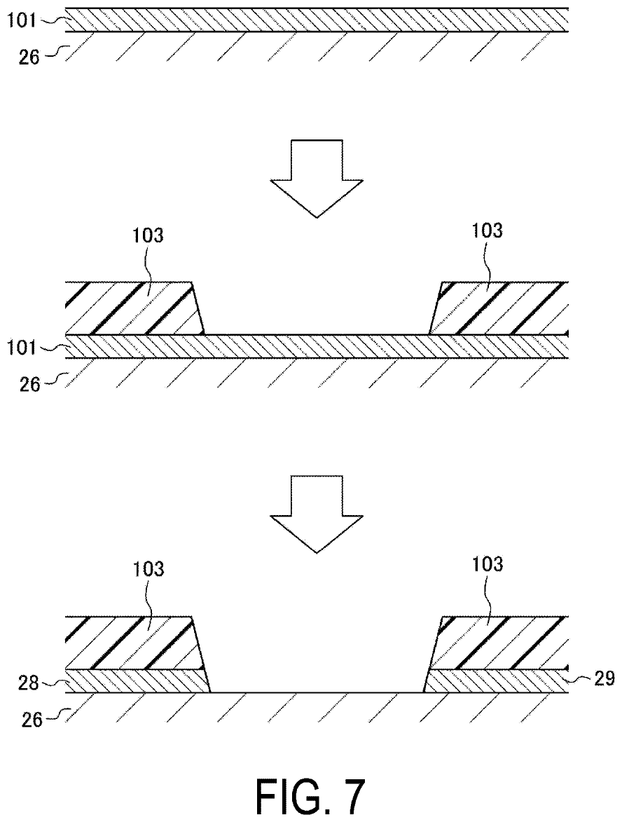

To be specific, on the substrate on which the first interlayer insulating film 26 is formed, a molybdenum film or a tungsten film is deposited, for example, by a sputtering technique. Thus, as illustrated in an upper diagram in FIG. 7, a first metal film 101 is formed. The first metal film 101 is an example of a conductive film. Next, a photosensitive resin is applied onto the substrate on which the first metal film 101 is formed, by a known coating method such as a spin coating method or a slit coating method, to form a coating film of the photosensitive resin.

Subsequently, the coating film of the photosensitive resin is pre-baked, exposed, developed, and post-baked. Thus, as illustrated in a middle diagram in FIG. 7, a first resist 103 is formed on the first metal film 101 at positions where the third terminal electrode 28 and the fourth terminal electrode 29 are to be formed. At this time, the first resist 103 is also formed at a position where the second capacitance electrode 30 is to be formed.

Then, using the first resist 103 as a mask, the first metal film 101 is dry etched. By patterning the first metal film 101 by dry etching in this way, the third terminal electrode 28 and the fourth terminal electrode 29 are formed as illustrated in a lower diagram in FIG. 7. At this time, the second capacitance electrode 30 is also formed by patterning the first metal film 101. Then, the first resist 103 is removed using a chemical solution.

In the terminal electrode forming step, the outer edge portion of the third terminal electrode 28 and the outer edge portion of the fourth terminal electrode 29 are formed into the tapered inclined surfaces 90 (see FIG. 6). In the terminal electrode forming step in this example, each of the third terminal electrode 28 and the fourth terminal electrode 29 is formed in a shape in which the semiconductor layer formable inclined surface 90a on which the second semiconductor layer 31 is formed forms the recessed portion 91 that is recessed outward in the channel length direction Dl in a plan view. In order to pattern the third terminal electrode 28 and the fourth terminal electrode 29 into such a shape, the first resist 103 is to be formed in that shape.

The rework step is performed after the terminal electrode forming step. In the rework step, a film residue 101r of the first metal film 101 is removed. In this example, the rework step is performed regardless of whether the film residue 101r of the first metal film 101 remains or not.

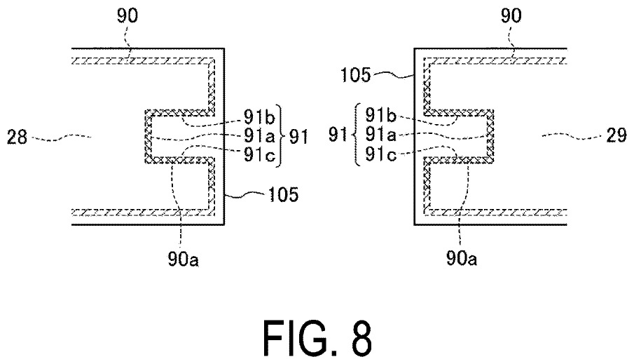

To be specific, a photosensitive resin is applied onto the substrate on which the third terminal electrode 28 and the fourth terminal electrode 29 are formed, by a known coating method such as a spin coating method or a slit coating method to form a coating film of the photosensitive resin. Subsequently, the coating film of the photosensitive resin is pre-baked, exposed, developed, and post-baked. Thus, as illustrated in FIG. 8, a second resist 105 is formed so as to cover the third terminal electrode 28 and the fourth terminal electrode 29 individually. At this time, the second resist 105 is also formed so as to cover the second capacitance electrode 30.

In this example, a shape of the second resist 105 corresponding to the third terminal electrode 28 is slightly larger than the external shape of the third terminal electrode 28 without the recessed portion 91 in a plan view. The second resist 105 is set at a position such that a peripheral edge surrounds the third terminal electrode 28 in a plan view. A shape of the second resist 105 corresponding to the fourth terminal electrode 29 is slightly larger than the outer shape of the fourth terminal electrode 29 without the recessed portion 91 in a plan view. The second resist 105 is set at a position such that a peripheral edge surrounds the fourth terminal electrode 29 in a plan view.

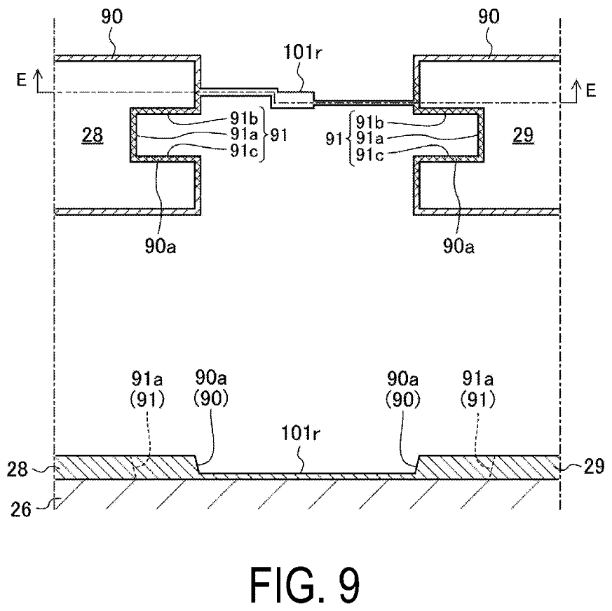

Then, a surface of the substrate on which the third terminal electrode 28 and the fourth terminal electrode 29 are formed is subjected to dry etching again using the second resist 105 as a mask. As illustrated in FIG. 9, when the film residue 101r of the first metal film 101 remains between the third terminal electrode 28 and the fourth terminal electrode 29, the third terminal electrode 28 and the fourth terminal electrode 29 may be connected via the film residue 101r, causing leakage between the third terminal electrode 28 and the fourth terminal electrode 29.

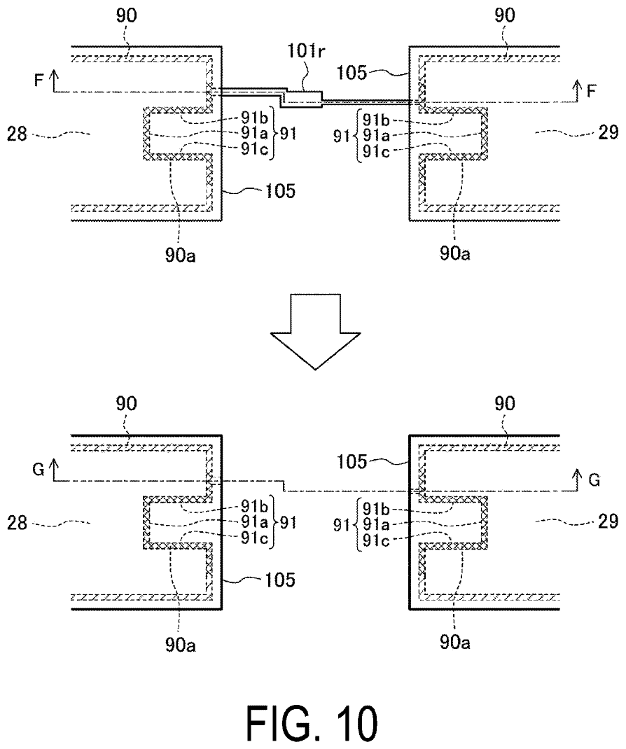

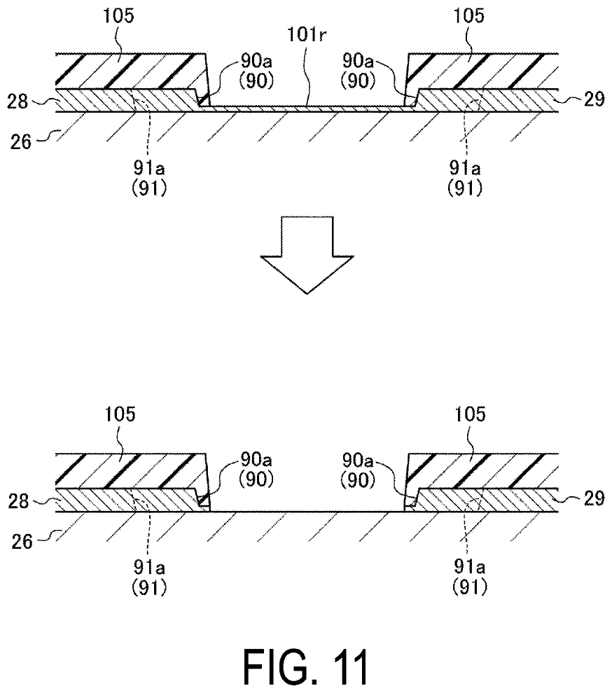

By performing the rework step, as illustrated in FIGS. 10 and 11, when the film residue 101r of the first metal film 101 remains, the film residue 101r is removed. Therefore, even when the third terminal electrode 28 and the fourth terminal electrode 29 are connected by the film residue 101r of the first metal film 101 before the rework step, the third terminal electrode 28 and the fourth terminal electrode 29 are separated by the removal of the film residue 101r in the rework step. Then, the second resist 105 is removed using a chemical solution.

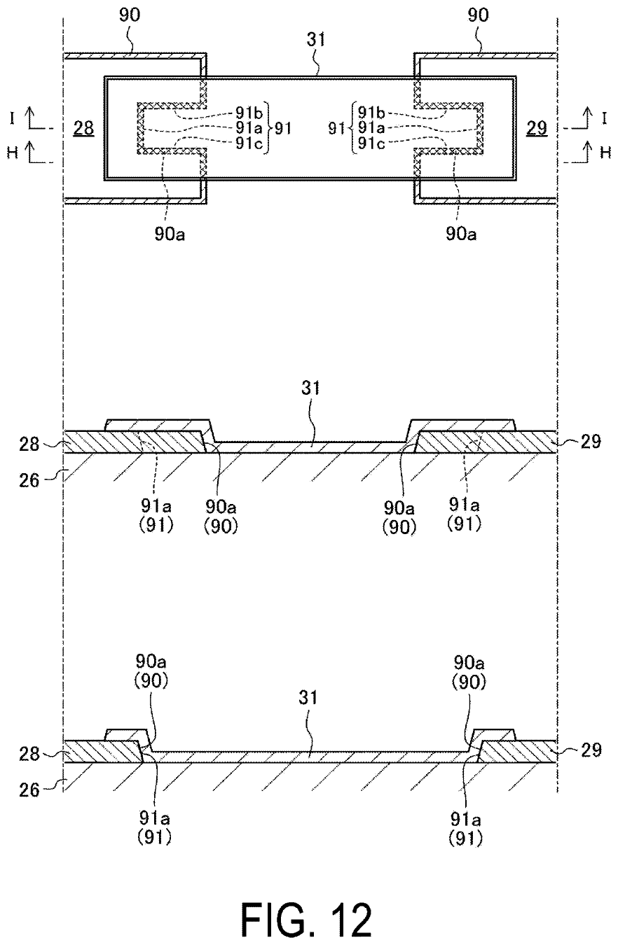

The semiconductor layer forming step is performed after the terminal electrode forming step. As illustrated in FIG. 12, in the semiconductor layer forming step, the second semiconductor layer 31 is formed so as to partially overlap both the third terminal electrode 28 and the fourth terminal electrode 29.

To be specific, a semiconductor film made of an oxide semiconductor such as InGaZnO₄ is deposited by, for example, a plasma CVD technique on the substrate on which the third terminal electrode 28 and the fourth terminal electrode 29 are formed. Subsequently, the semiconductor film is patterned to form the second semiconductor layer 31 so as to partially overlap both the third terminal electrode 28 and the fourth terminal electrode 29.

The gate insulating film and electrode forming step is performed after the semiconductor layer forming step. The gate insulating film and electrode forming step corresponds to a gate insulating film forming step and a gate electrode forming step. In the gate insulating film and electrode forming step, the second gate insulating film 32 is formed on the second semiconductor layer 31, and the second gate electrode 33 is formed on the second gate insulating film 32.

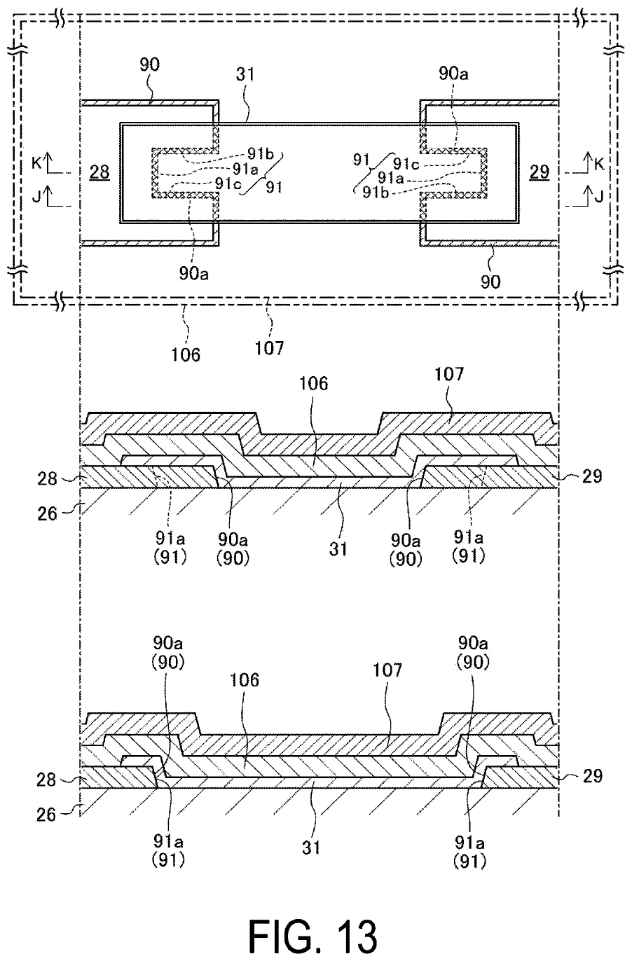

To be specific, a silicon oxide film or the like is deposited by, for example, a plasma CVD technique on the substrate on which the second semiconductor layer 31 is formed. Thus, a first insulating film 106 is formed so as to cover the second semiconductor layer 31. Subsequently, on the substrate on which the first insulating film 106 is formed, a molybdenum film or a tungsten film is deposited, or a titanium film (or a titanium alloy film), an aluminum film (or an aluminum alloy film), and a titanium film (or a titanium alloy film) are deposited in this order, for example, by a sputtering technique. Thus, as illustrated in FIG. 13, a second metal film 107 is formed so as to cover the first insulating film 106. In an upper diagram in FIG. 13, for convenience, the first insulating film 106 and the second metal film 107 are conceptually illustrated by two-dot chain lines.

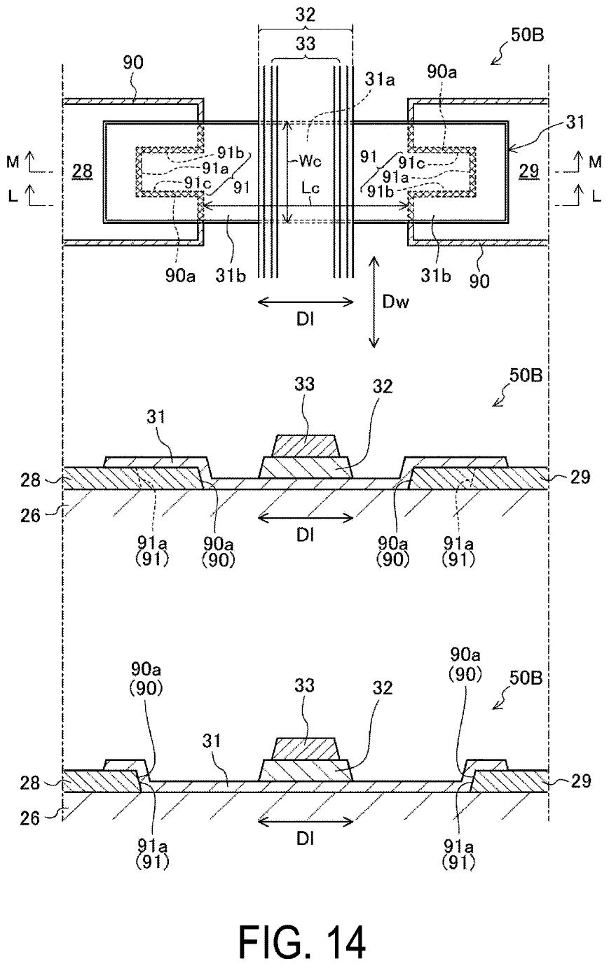

Then, the first insulating film 106 and the second metal film 107 are patterned to form the second gate insulating film 32 and the second gate electrode 33, as illustrated in FIG. 14. That is, first, a third resist is formed on the second metal film 107 at a position where the second gate electrode 33 is to be formed, and then the second metal film 107 is etched using the third resist as a mask. Thus, the second gate electrode 33 is formed. Subsequently, the first insulating film 106 is etched using the same third resist as a mask. Thus, the second gate insulating film 32 is formed.

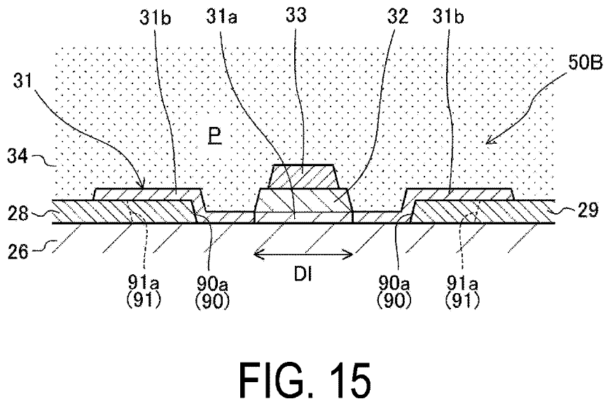

Thereafter, as illustrated in FIG. 15, the substrate on which the second gate electrode 33 is formed is subjected to a hydrogen plasma treatment using the second gate insulating film 32 and the second gate electrode 33 as a mask. The hydrogen plasma treatment exposes exposed portions of the second semiconductor layer 31 to plasma P. The portions of the second semiconductor layer 31 exposed to the plasma P experience oxygen deficiency, resulting in low resistance. Thus, the second semiconductor layer 31 is partially made conductive, forming the channel region 31a and the pair of conductive regions 31b.

In this manner, the second TFT 50B can be fabricated.

The step of forming the TFT layer 20 further includes an interlayer insulating film forming step, a contact hole forming step, a cleaning step, a wiring line forming step, and a flattening film forming step.

The interlayer insulating film forming step is performed after the step of fabricating the second TFT 50B. In the interlayer insulating film forming step, a silicon oxide film and a silicon nitride film are deposited in sequence, for example, by a plasma CVD technique. Thus, the second interlayer insulating film 34 is formed.

The contact hole forming step is performed after the interlayer insulating film forming step. In the contact hole forming step, the first gate insulating film 23, the first interlayer insulating film 26, and the second interlayer insulating film 34 are patterned to form the first contact hole Ha, the second contact hole Hb (the hole that also passes through the second interlayer insulating film 34), the third contact hole Hc, the fifth contact hole He, and the sixth contact hole Hf in the first gate insulating film 23, the first interlayer insulating film 26, and the second interlayer insulating film 34.

At this time, the first contact hole Ha is formed so as to expose the first gate electrode 24 at a bottom thereof. The second contact hole Hb (the hole that also passes through the second interlayer insulating film 34) is formed so as to expose the conductive region 22b of the first semiconductor layer 22 at a bottom thereof. The third contact hole Hc is formed so as to expose the metal layer 27 at a bottom thereof. The fifth contact hole He is formed so as to expose the relay line 40r at a bottom thereof. The sixth contact hole Hf is formed so as to expose the second gate electrode 33 at a bottom thereof.

The cleaning step is performed after the contact hole forming step. In the cleaning step, a cleaning process is performed on the second interlayer insulating film 34. The cleaning process is wet cleaning using a cleaning liquid. In the cleaning process, the inside of the first contact hole Ha, the inside of the second contact hole Hb (the hole that also passes through the second interlayer insulating film 34), the inside of the third contact hole Hc, the inside of the fifth contact hole He, and the inside of the sixth contact hole Hf are also cleaned. For example, a hydrofluoric acid solution is used as the cleaning liquid.

The wiring line forming step is performed after the cleaning step. In the wiring line forming step, for example, a titanium film (or a titanium alloy film), an aluminum film (an aluminum alloy film), and a titanium film (a titanium alloy film) are deposited in this order by a sputtering technique. Thus, a metal layered film is formed. Subsequently, the metal layered film is patterned to form the first to fourth connection lines 40ca, 40cb, 40cc, and 40cd, at least one of the first terminal electrode 36 and the second terminal electrode 37, the power source line 40p, and the source line 40s.

At this time, the first connection line 40ca is formed so as to be connected to the first gate electrode 24 via the first contact hole Ha. At least one of the first terminal electrode 36 and the second terminal electrode 37 is formed so as to be connected to the first semiconductor layer 22 via the second contact hole Hb. The second connection line 40cb is formed so as to be connected to the metal layer 27 via the third contact hole Hc. The third connection line 40cc is formed so as to be connected to the relay line 40r via the fifth contact hole He. The fourth connection line 40cd is formed so as to be connected to the second gate electrode 33 via the sixth contact hole Hf.

The flattening film forming step is performed after the wiring line forming step. In the flattening film forming step, a photosensitive resin is applied onto the substrate on which the first to fourth connection lines 40ca, 40cb, 40cc, and 40cd, and the like are formed, for example, by a known coating method such as a spin coating method or a slit coating method to form a coating film of the photosensitive resin. Subsequently, the coating film of the photosensitive resin is pre-baked, exposed, developed, and post-baked. Thus, the flattening film 58 having the seventh contact hole Hg is formed.

In this manner, the TFT layer 20 can be formed.

### Case Where Second Resist Formation Position Is Shifted in Rework Step

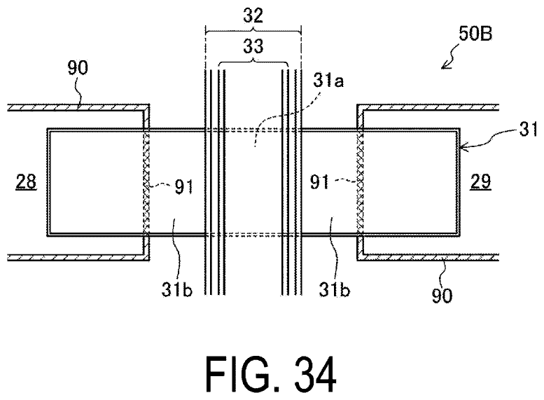

In the rework step described above, misalignment may occur in the position where the second resist 105 is formed. Due to this, as illustrated in FIG. 34, when semiconductor layer formable inclined surfaces 90a of a third terminal electrode 28 and a fourth terminal electrode 29 of a second TFT 50B to be fabricated are linear, a connection failure may occur between a second semiconductor layer 31 and the third terminal electrode 28 or the fourth terminal electrode 29.

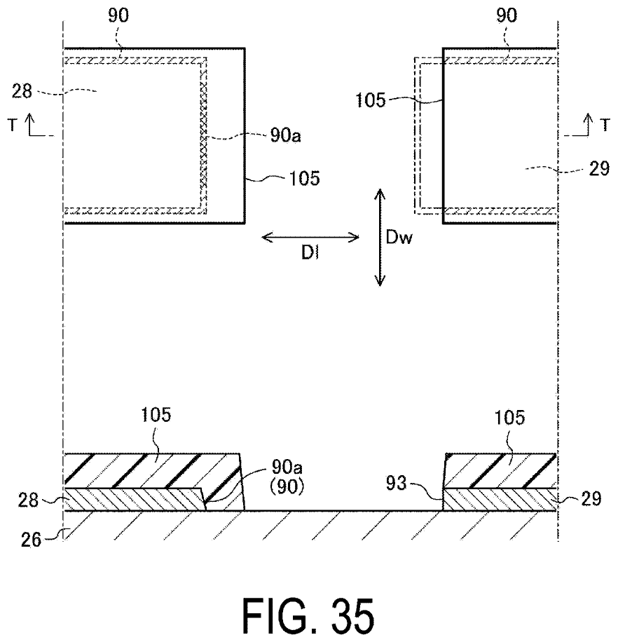

That is, as illustrated in FIG. 35, when misalignment occurs in a formation position of a second resist 105 in a channel length direction Dl, the entire semiconductor layer formable inclined surface 90a of the third terminal electrode 28 or the fourth terminal electrode 29 (the fourth terminal electrode 29 in the example illustrated in FIG. 35) is exposed from the second resist 105 (indicated by two-dot chain lines in an upper diagram in FIG. 35). When this happens, a portion of the third terminal electrode 28 or the fourth terminal electrode 29 exposed from the second resist 105 is removed by dry etching in the rework step.

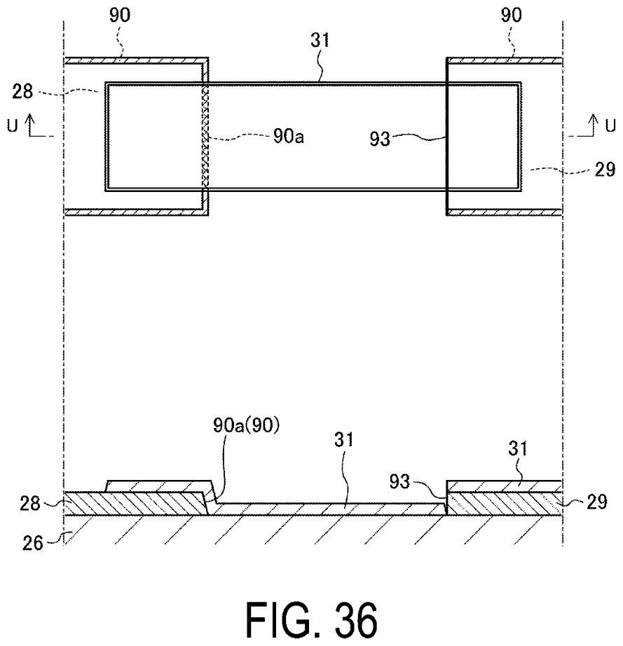

End faces (hereinafter referred to as reworked end faces) 93 of the third terminal electrode 28 and the fourth terminal electrode 29 formed by dry etching are formed with a steep slope at a right angle or an approximately right angle (see a lower diagram in FIG. 35). Thereafter, when the second semiconductor layer 31 is formed, as illustrated in FIG. 36, the second semiconductor layer 31 may become extremely thin or may be discontinued and divided at the reworked end face 93 (indicated by a thick line in the upper diagram in FIG. 36) of the third terminal electrode 28 or the fourth terminal electrode 29. Thus, a connection failure may occur between the second semiconductor layer 31 and the third terminal electrode 28 or the fourth terminal electrode 29.

As a countermeasure against such a connection failure, in the second TFT 50B according to the first embodiment, as described above, the recessed portions 91 are provided in the third terminal electrode 28 and the fourth terminal electrode 29, respectively. Thus, connection between the second semiconductor layer 31 and the third terminal electrode 28 and the fourth terminal electrode 29 are ensured.

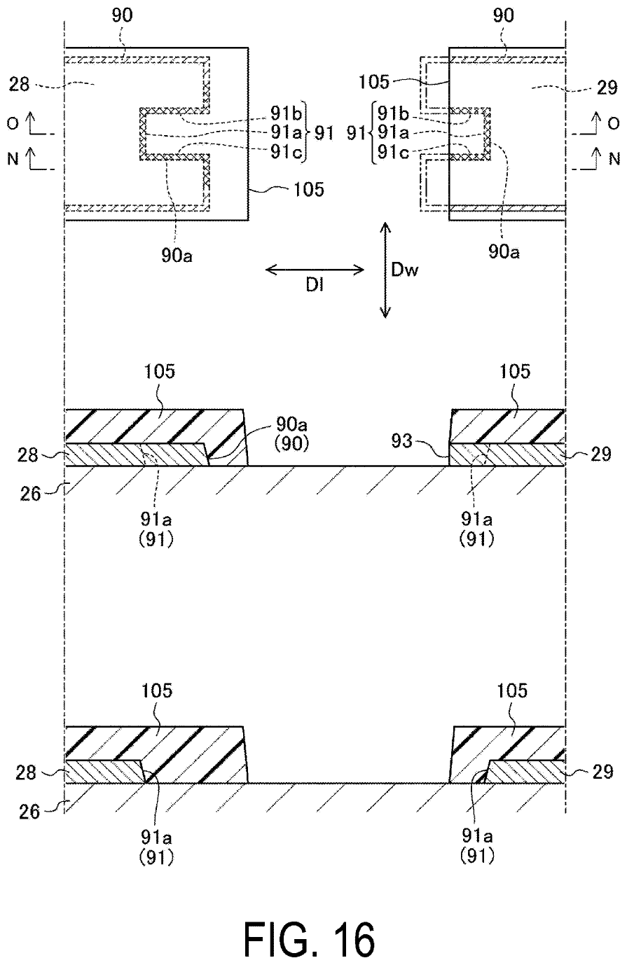

For example, as illustrated in FIG. 16, when the formation position of the second resist 105 is shifted from a desired position to one side in the channel length direction Dl (the right side of the paper in FIG. 16), specifically, when the formation position of the second resist 105 corresponding to the third terminal electrode 28 is shifted closer to the fourth terminal electrode 29 and the formation position of the second resist 105 corresponding to the fourth terminal electrode 29 is shifted away from the third terminal electrode 28, a portion of the third terminal electrode 28 on the channel region 31a side is covered with the second resist 105, but a portion of the fourth terminal electrode 29 on the channel region 31a side is exposed from the second resist 105 (a state illustrated by two-dot chain lines in an upper diagram in FIG. 16).

When this happens, the portion of the fourth terminal electrode 29 exposed from the second resist 105, that is, both side portions of the open end of the recessed portion 91, are removed by dry etching in the rework step. The reworked end faces 93 of the fourth terminal electrode 29 formed by this dry etching is formed with a steep slope at a right angle or an approximately right angle (see a middle diagram in FIG. 16).

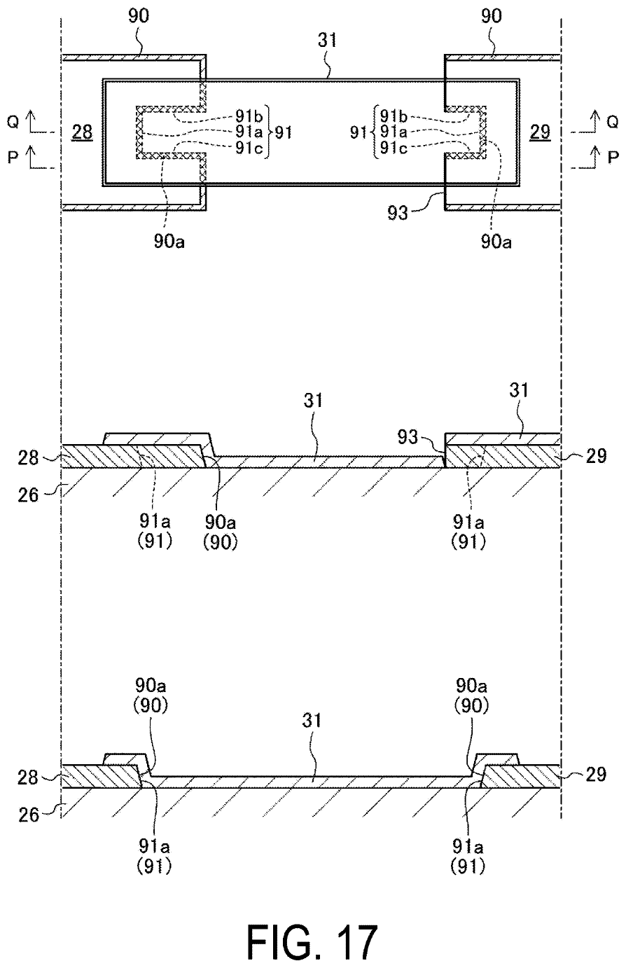

When the second semiconductor layer 31 is formed so as to partially overlap the fourth terminal electrode 29 and the third terminal electrode 28 in such a state, as illustrated in FIG. 17, the second semiconductor layer 31 is formed continuously from the outside of the third terminal electrode 28 along the semiconductor layer formable inclined surface 90a to the top of the third terminal electrode 28 and is thereby connected to the third terminal electrode 28. However, the second semiconductor layer 31 may become extremely thin or may be discontinued and divided at the reworked end faces 93 (indicated by thick lines in an upper diagram in FIG. 17) of the fourth terminal electrode 29 (see a middle diagram in FIG. 17).

However, the semiconductor layer formable inclined surface 90a of the fourth terminal electrode 29 remains in part of the recessed portion 91 covered with the second resist 105. Therefore, even when the second semiconductor layer 31 is divided at the reworked end faces 93, the second semiconductor layer 31 is formed continuously from the outside of the fourth terminal electrode 29 along the semiconductor layer formable inclined surface 90a of the recessed portion 91 to the top of the fourth terminal electrode 29 (see a lower diagram in FIG. 17). Thus, connection between the second semiconductor layer 31 and the fourth terminal electrode 29 is ensured.

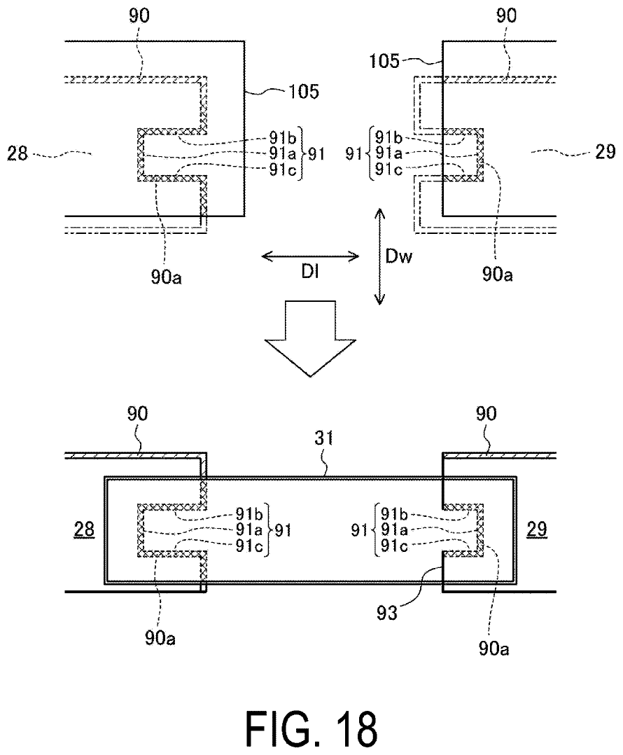

For example, as illustrated in FIG. 18, when the formation position of the second resist 105 is also shifted from the desired position to one side in the channel width direction Dw (the upper side of the paper in FIG. 18), a portion of the inclined surface 90 of the fourth terminal electrode 29 other than the semiconductor layer formable inclined surface 90a is exposed from the second resist 105 and is removed by dry etching in the rework step, thereby forming the reworked end face 93 (indicated by a thick line in a lower diagram in FIG. 18). However, even in this case, the semiconductor layer formable inclined surface 90a of the fourth terminal electrode 29 remains in part of the recessed portion 91, so that connection between the second semiconductor layer 31 and the fourth terminal electrode 29 is ensured.

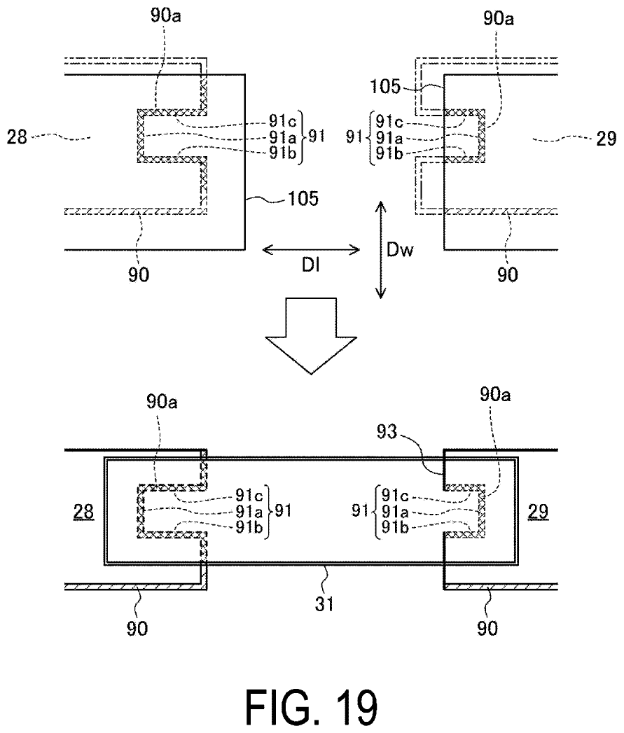

For example, as illustrated in FIG. 19, when the formation position of the second resist 105 is also shifted from the desired position to the other side in the channel width direction Dw (the lower side of the paper in FIG. 19), a portion of the inclined surface 90 of the fourth terminal electrode 29 other than the semiconductor layer formable inclined surface 90a is exposed from the second resist 105 and is removed by dry etching in the rework step, thereby forming the reworked end face 93 (indicated by a thick line in the lower diagram in FIG. 19). However, even in this case, the semiconductor layer formable inclined surface 90a of the fourth terminal electrode 29 remains in part of the recessed portion 91, so that connection between the second semiconductor layer 31 and the fourth terminal electrode 29 is ensured.

These can also be applied when the formation position of the second resist 105 is shifted from the desired position to the other side in the channel length direction Dl (the left side of the paper in FIG. 8), specifically, when the formation position of the second resist 105 corresponding to the third terminal electrode 28 is shifted away from the fourth terminal electrode 29 and the formation position of the second resist 105 corresponding to the fourth terminal electrode 29 is shifted closer to the third terminal electrode 28, and connection between the second semiconductor layer 31 and the third terminal electrode 28 and the fourth terminal electrode 29 are ensured.

That is, in this case, the second semiconductor layer 31 is formed continuously from the outside of the fourth terminal electrode 29 along the semiconductor layer formable inclined surface 90a to the top of the fourth terminal electrode 29 and is thereby connected to the fourth terminal electrode 29, while the second semiconductor layer 31 may become extremely thin or discontinued and divided at the reworked end faces 93 of the third terminal electrode 28. However, the second semiconductor layer 31 is formed continuously from the outside of the third terminal electrode 28 along the semiconductor layer formable inclined surface 90a of the recessed portion 91 to the top of the third terminal electrode 28. Thus, connection between the second semiconductor layer 31 and the third terminal electrode 28 is ensured.

### Advantages of First Embodiment

In the second TFT 50B according to the first embodiment, the semiconductor layer formable inclined surfaces 90a of the third terminal electrode 28 and the fourth terminal electrode 29 for the second semiconductor layer 31 form the recessed portions 91 recessed outward in the channel length direction Dl in a plan view. According to this configuration, in the fabrication of the second TFT 50B, even when misalignment occurs in the formation position of the second resist 105 used as a mask in the rework step of removing the film residue 101r of the first metal film 101 between the third terminal electrode 28 and the fourth terminal electrode 29, portions having a good inclined surface state that are not etched can be left on the semiconductor layer formable inclined surfaces 90a of the third terminal electrode 28 and the fourth terminal electrode 29. Thus, at least part of the second semiconductor layer 31 can be provided with an appropriate thickness so as to be formed on the third terminal electrode 28 and the fourth terminal electrode 29 without interruption. This suppresses a connection failure between the semiconductor layer 31 and both the third terminal electrode 28 and the fourth terminal electrode 29.

In the second TFT 50B according to the first embodiment, the recessed portion 91 is formed in the shape of a rectangular cutout shape. Such a recessed portion 91 is composed of the second edge portion 91b and the third edge portion 91c facing each other, and the first edge portion 91a connecting the second edge portion 91b and the third edge portion 91c at the back side of the recessed portion 91. The semiconductor layer formable inclined surfaces 90a of the first to third edge portions 91a, 91b, and 91c face directions different from each other. Thus, even when misalignment occurs in the formation position of the second resist 105 used as a mask in the rework step, portions having a good inclined surface states that are not etched can be ensured in the semiconductor layer formable inclined surfaces 90a facing at least two different directions in the recessed portions 91 of the third terminal electrode 28 and the fourth terminal electrode 29.

In the second TFT 50B according to the first embodiment, the third terminal electrode 28 and the fourth terminal electrode 29 are each made of a metal material containing molybdenum (Mo) or tungsten (W). Molybdenum (Mo) and tungsten (W) are corrosion resistant to hydrofluoric acid. Therefore, in the step of forming the TFT layer 20, when cleaning the inside of the first contact hole Ha, the inside of the second contact hole Hb (the hole that also passes through the second interlayer insulating film 34), the inside of the third contact hole Hc, and the insides of the fifth and sixth contact holes He and Hf, a hydrofluoric acid solution can be used as a cleaning liquid.

The organic EL display device 1 according to the first embodiment includes the second TFT 50B described above. The second TFT 50B can suppress a connection failure between the third terminal electrode 28 and the fourth terminal electrode 29 and the second semiconductor layer 31. Thus, a manufacturing yield of the organic EL display device 1 can be improved.

In the method of manufacturing the organic EL display device 1 according to the first embodiment, in the terminal electrode forming step, the outer edge portions of the third terminal electrode 28 and the fourth terminal electrode 29 are formed into the tapered inclined surfaces 90. Then, the third terminal electrode 28 and the fourth terminal electrode 29 are formed into shapes in which the semiconductor layer formable inclined surfaces 90a form recessed portions 91 recessed outward in the channel length direction Dl in a plan view. According to this configuration, even when misalignment occurs in the formation position of the second resist 105 in the rework step, portions having a good inclined surface state that are not etched can be left on the semiconductor layer formable inclined surfaces 90a of the third terminal electrode 28 and the fourth terminal electrode 29. Thus, at least part of the second semiconductor layer 31 can be provided with an appropriate thickness so as to be formed on the third terminal electrode 28 and the fourth terminal electrode 29 without interruption. This suppresses a connection failure between the second semiconductor layer 31 and both the third terminal electrode 28 and the fourth terminal electrode 29.

In the method of manufacturing the organic EL display device 1 according to the first embodiment, in the semiconductor layer forming step, the second semiconductor layer 31 is formed of an oxide semiconductor. Then, in the cleaning step, the inside of the third contact hole Hc in the second interlayer insulating film 34 is cleaned with a cleaning liquid. At this time, when the third contact hole Hc reaches the second semiconductor layer 31, the second semiconductor layer 31 is exposed to the cleaning liquid. The second semiconductor layer 31, which is made of an oxide semiconductor, is easily dissolved or corroded when exposed to the cleaning liquid.

However, in the method of manufacturing the organic EL display device 1 according to the first embodiment, the third contact hole Hc reaches not the second semiconductor layer 31 but the metal layer 27 forming the third terminal electrode 28 or the fourth terminal electrode 29 connected to the second semiconductor layer 31. Therefore, even when the cleaning process is performed, the second semiconductor layer 31 is not exposed to the cleaning liquid, and the second semiconductor layer 31 can be prevented from being dissolved or corroded. A portion of the metal layer 27 exposed in the third contact hole Hc can be kept clean. Thus, the second connection line 40cb formed in the wiring line forming step can be suitably connected to the metal layer 27 via the third contact hole Hc.

In the method of manufacturing the organic EL display device 1 according to the first embodiment, in the terminal electrode forming step, the third terminal electrode 28 and the fourth terminal electrode 29 are formed of a metal material containing molybdenum (Mo) or tungsten (W). Molybdenum (Mo) or tungsten (W) is corrosion resistant to hydrofluoric acid. Therefore, when cleaning the inside of the first contact hole Ha, the inside of the second contact hole Hb (the hole that also passes through the second interlayer insulating film 34), the inside of the third contact hole Hc, and the insides of the fifth and sixth contact holes He and Hf in the cleaning step, a hydrofluoric acid aqueous solution can be used as the cleaning liquid. The hydrofluoric acid aqueous solution is suitable as the cleaning liquid because the hydrofluoric acid aqueous solution is relatively corrosive.

### Modified Example

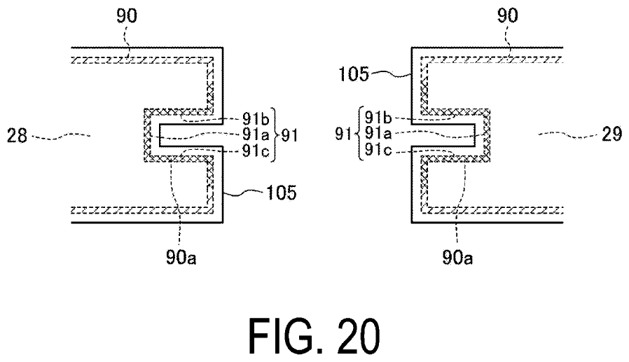

In this modified example, in the method of manufacturing the organic EL display device 1, a shape of the second resist 105 formed in the rework step differs from that according to the first embodiment. As illustrated in FIG. 20, in this modified example, the shape of the second resist 105 corresponding to the third terminal electrode 28 is similar to the external shape of the third terminal electrode 28 but slightly larger in a plan view. The shape of the second resist 105 corresponding to the fourth terminal electrode 29 is similar to the external shape of the fourth terminal electrode 29 but slightly larger in a plan view.

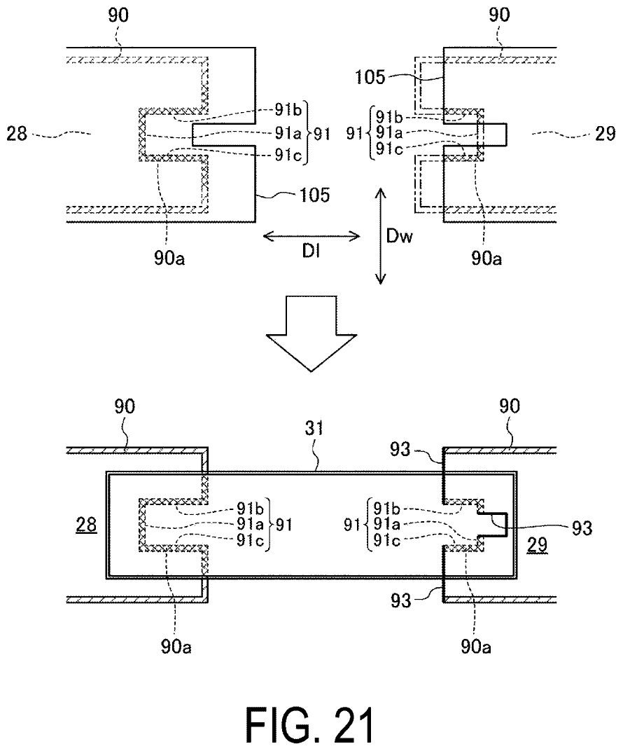

In the rework step, for example, as illustrated in FIG. 21, when a formation position of the second resist 105 is shifted from a desired position to one side in the channel length direction Dl (the right side of the paper in FIG. 21), specifically, when the formation position of the second resist 105 corresponding to the third terminal electrode 28 is shifted closer to the fourth terminal electrode 29 and the formation position of the second resist 105 corresponding to the fourth terminal electrode 29 is shifted away from the third terminal electrode 28, a portion of the third terminal electrode 28 on the channel region 31a side is covered with the second resist 105, but portions on the channel region 31a side and a back side portion of the recessed portion 91 in the fourth terminal electrode 29 are exposed from the second resist 105 (a state illustrated by two-dot chain lines in an upper diagram in FIG. 21).

When this happens, the portions of the fourth terminal electrode 29 exposed from the second resist 105, that is, both side portions of the recessed portion 91 and part of the first edge portion 91a of the recessed portion 91 are removed by dry etching in the rework step. The reworked end faces 93 (indicated by thick lines in a lower diagram in FIG. 21) of the fourth terminal electrode 29 formed by this dry etching is formed with a steep slope at a right angle or an approximately right angle.

When the second semiconductor layer 31 is formed so as to partially overlap the fourth terminal electrode 29 and the third terminal electrode 28 in such a state, the second semiconductor layer 31 is formed continuously from the outside of the third terminal electrode 28 along the semiconductor layer formable inclined surface 90a to the top of the third terminal electrode 28 and is thereby connected to the third terminal electrode 28. However, the second semiconductor layer 31 may become extremely thin or may be discontinued and divided at the reworked end faces 93 of the fourth terminal electrode 29.

However, the semiconductor layer formable inclined surfaces 90a of the recessed portion 91 of the fourth terminal electrode 29 remains at portions covered with the second resist 105. Therefore, even when the second semiconductor layer 31 is divided at the reworked end faces 93, the second semiconductor layer 31 is formed continuously from the outside of the fourth terminal electrode 29 along the semiconductor layer formable inclined surfaces 90a of the recessed portion 91 to the top of the fourth terminal electrode 29. Thus, connection between the second semiconductor layer 31 and the fourth terminal electrode 29 is ensured.

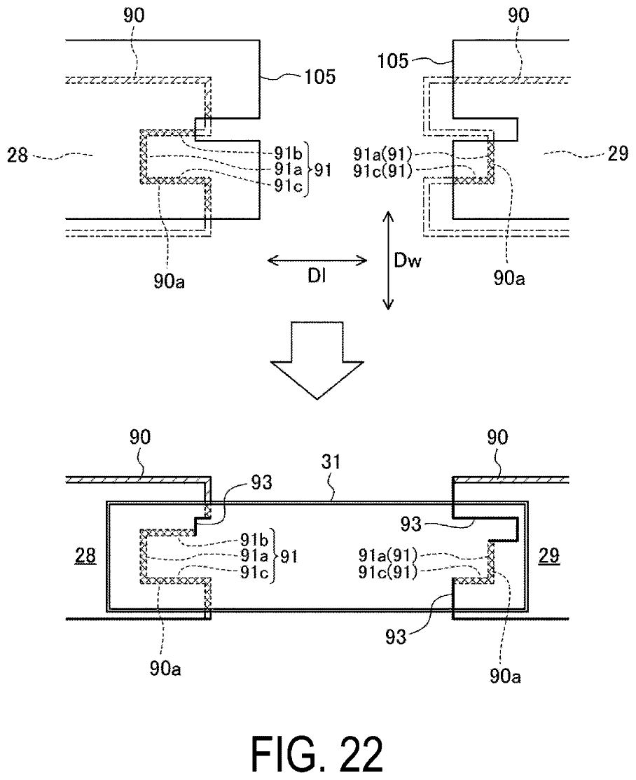

For example, as illustrated in FIG. 22, when the formation position of the second resist 105 is also shifted from the desired position to one side in the channel width direction Dw (the upper side of the paper in FIG. 22), a portion of the semiconductor layer formable inclined surface 90a of the third terminal electrode 28 and portions of the inclined surfaces 90 of the third terminal electrode 28 and the fourth terminal electrode 29 other than the semiconductor layer formable inclined surfaces 90a are also exposed from the second resist 105 and are removed by dry etching in the rework step, thereby forming the reworked end faces 93 (indicated by thick lines in a lower diagram in FIG. 22). However, even in this case, the semiconductor layer formable inclined surfaces 90a remain in portions of the recessed portions 91 in both the third terminal electrode 28 and the fourth terminal electrode 29, so that connection between the second semiconductor layer 31 and the third terminal electrode 28 and the fourth terminal electrode 29 are ensured.

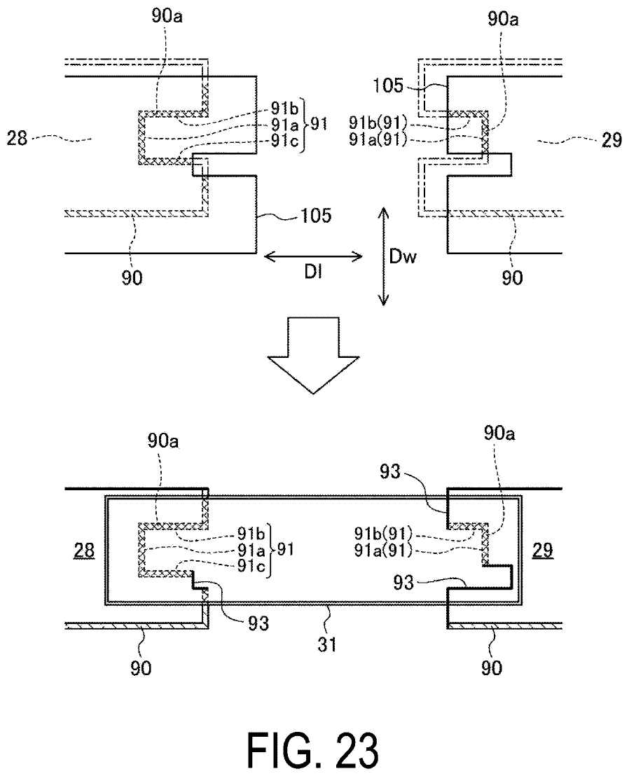

For example, as illustrated in FIG. 23, when the formation position of the second resist 105 is also shifted from the desired position to the other side in the channel width direction Dw (the lower side of the paper in FIG. 23), a portion of the semiconductor layer formable inclined surface 90a of the third terminal electrode 28 and portions of the inclined surfaces 90 of the third terminal electrode 28 and the fourth terminal electrode 29 other than the semiconductor layer formable inclined surfaces 90a are exposed from the second resist 105 and are removed by dry etching in the rework step, thereby forming the reworked end faces 93 (indicated by thick lines in a lower diagram in FIG. 23). However, even in this case, the semiconductor layer formable inclined surfaces 90a remain in portions of the recessed portions 91 in both the third terminal electrode 28 and the fourth terminal electrode 29, so that connection between the second semiconductor layer 31 and the third terminal electrode 28 and the fourth terminal electrode 29 are ensured.

These can also be applied when the formation position of the second resist 105 is shifted from the desired position to the other side in the channel length direction Dl (the left side of the paper in FIG. 20), specifically, when the formation position of the second resist 105 corresponding to the third terminal electrode 28 is shifted away from the fourth terminal electrode 29 and the formation position of the second resist 105 corresponding to the fourth terminal electrode 29 is shifted closer to the third terminal electrode 28, and connection between the second semiconductor layer 31 and the third terminal electrode 28 and the fourth terminal electrode 29 are ensured.

### Second Embodiment

An organic EL display device 1 according to a second embodiment differs from that according to the first embodiment in a configuration of a second TFT 50B. Note that, in the following embodiments, the organic EL display device 1 is configured in a similar manner to that in the first embodiment except that the configuration of the second TFT 50B differs from that according to the first embodiment.

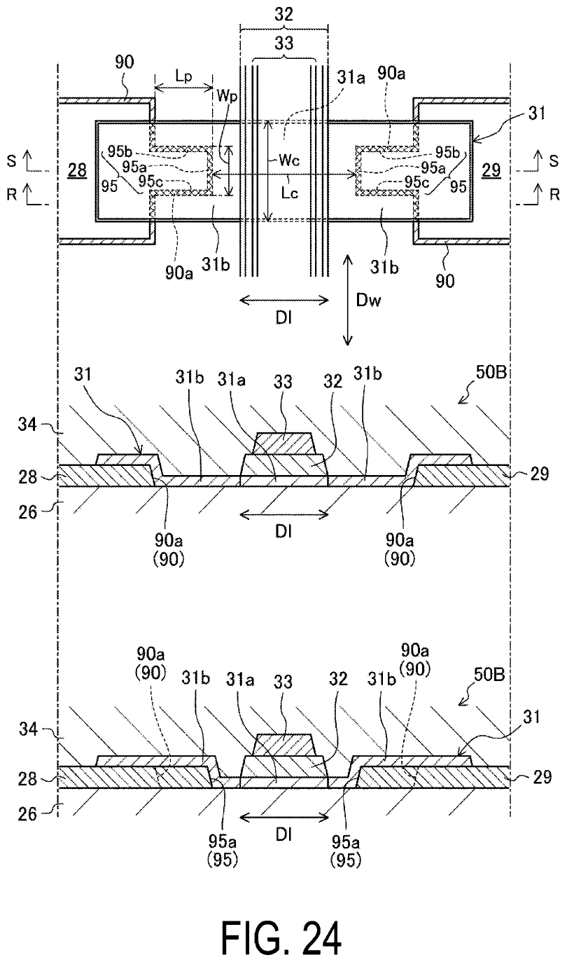

As illustrated in FIG. 24, in the second TFT 50B according to the second embodiment, semiconductor layer formable inclined surfaces 90a of a third terminal electrode 28 and a fourth terminal electrode 29 form protruding portions 95 that protrude inward in a channel length direction Dl in a plan view. In this example, the protruding portion 95 is provided in each of the third terminal electrode 28 and the fourth terminal electrode 29. The protruding portion 95 has at least one corner or inflection point.

Each of the protruding portion 95 of the third terminal electrode 28 and the protruding portion 95 of the fourth terminal electrode 29 is formed in a shape of a rectangular protrusion having two corners or inflection points. Each protruding portion 95 is composed of a fourth edge portion 95a, a fifth edge portion 95b, and a sixth edge portion 95c. The fourth edge portion 95a is located at a tip of the protruding portion 95 and is a portion of an outer edge of the protruding portion 95 that faces a channel region 31a in a plan view. The fifth edge portion 95b and the sixth edge portion 95c extend from different end portions of the fourth edge portion 95a toward an opposite side to the channel region 31a in a plan view and are portions of the outer edge of the protruding portion 95 that face directions away from each other.

A length Lp of each protruding portion 95 is, for example, 500 nm or more and 10000 nm or less. A width Wp of each protruding portion 95 is, for example, 1000 nm or more and 20000 nm or less. Here, the length Lp of the protruding portion 95 denotes a dimension of the protruding portion 95 in the channel length direction Dl. The width Wp of the protruding portion 95 is a dimension of the protruding portion 95 in a channel width direction Dw. The length Lp and the width Wp of the protruding portion 95 are equal in the third terminal electrode 28 and the fourth terminal electrode 29. At least one of the length Lp and the width Wp of the protruding portion 95 may be different in the third terminal electrode 28 and the fourth terminal electrode 29.

One conductive region 31b of a second semiconductor layer 31 extends from the outside of the third terminal electrode 28 (the channel region 31a side) onto the third terminal electrode 28 via the semiconductor layer formable inclined surface 90a. The one conductive region 31b of the second semiconductor layer 31 extends on the semiconductor layer formable inclined surface 90a in at least part of the protruding portion 95 and is formed continuously on the third terminal electrode 28, thereby ensuring connection between the second semiconductor layer 31 and the third terminal electrode 28.

The other conductive region 31b of the second semiconductor layer 31 extends from the outside of the fourth terminal electrode 29 (the channel region 31a side) onto the fourth terminal electrode 29 via the semiconductor layer formable inclined surface 90a. The other conductive region 31b of the second semiconductor layer 31 extends on the semiconductor layer formable inclined surface 90a in at least part of the protruding portion 95 and is formed continuously on the fourth terminal electrode 29, thereby ensuring connection between the second semiconductor layer 31 and the fourth terminal electrode 29.

### Rework Step

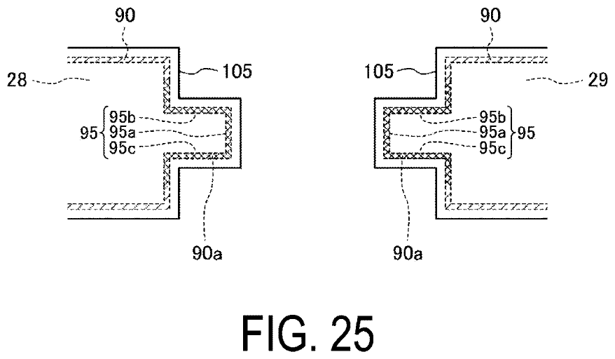

A shape of a second resist 105 formed in a rework step according to the second embodiment differs from that according to the first embodiment. As illustrated in FIG. 25, in this example, the shape of the second resist 105 corresponding to the third terminal electrode 28 is similar to the external shape of the third terminal electrode 28 but slightly larger in a plan view. The shape of the second resist 105 corresponding to the fourth terminal electrode 29 is similar to the external shape of the fourth terminal electrode 29 but slightly larger in a plan view.

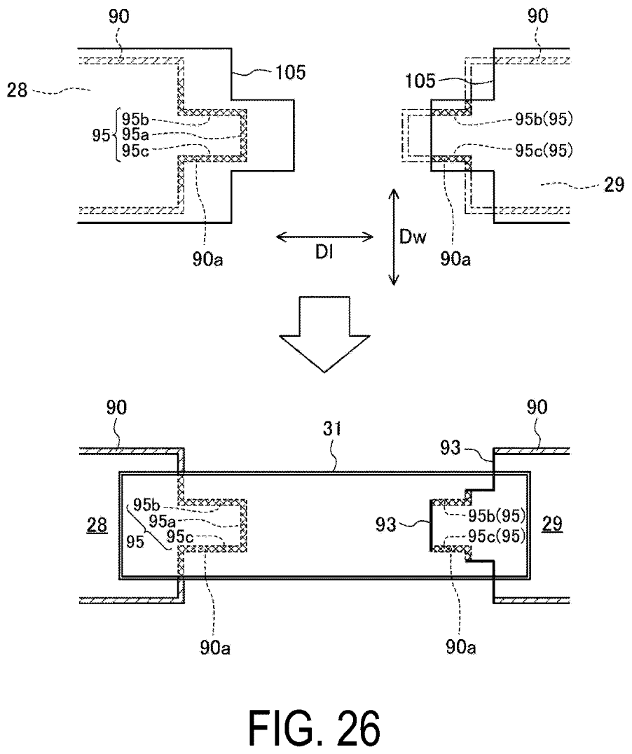

In the rework step, for example, as illustrated in FIG. 26, when a formation position of the second resist 105 is shifted from a desired position to one side in the channel length direction Dl, specifically, when the formation position of the second resist 105 corresponding to the third terminal electrode 28 is shifted closer to the fourth terminal electrode 29 and the formation position of the second resist 105 corresponding to the fourth terminal electrode 29 is shifted away from the third terminal electrode 28, a portion of the third terminal electrode 28 on the channel region 31a side is covered with the second resist 105, but a portion of the fourth terminal electrode 29 on the channel region 31a side is exposed from the second resist 105 (a state illustrated by two-dot chain lines in an upper diagram in FIG. 26).

When this happens, the portion of the fourth terminal electrode 29 exposed from the second resist 105, specifically, a tip portion and both sides of a base end portion of the protruding portion 95 in the fourth terminal electrode 29 are removed by dry etching in the rework step. Reworked end faces 93 (indicated by thick lines in a lower diagram in FIG. 26) of the fourth terminal electrode 29 formed by this dry etching is formed with a steep slope at a right angle or an approximately right angle.

When the second semiconductor layer 31 is formed so as to partially overlap the fourth terminal electrode 29 and the third terminal electrode 28 in such a state, the second semiconductor layer 31 is formed continuously from the outside of the third terminal electrode 28 along the semiconductor layer formable inclined surface 90a to the top of the third terminal electrode 28 and is thereby connected to the third terminal electrode 28. However, the second semiconductor layer 31 may become extremely thin or may be discontinued and divided at the reworked end faces 93 of the fourth terminal electrode 29.

However, the semiconductor layer formable inclined surface 90a of the fourth terminal electrode 29 remains in part of the protruding portion 95 covered with the second resist 105. Therefore, even when the second semiconductor layer 31 is divided at the reworked end faces 93, the second semiconductor layer 31 is formed continuously from the outer side of the fourth terminal electrode 29 along the semiconductor layer formable inclined surfaces 90a of the protruding portion 95 to the top of the fourth terminal electrode 29. Thus, connection between the second semiconductor layer 31 and the fourth terminal electrode 29 is ensured.

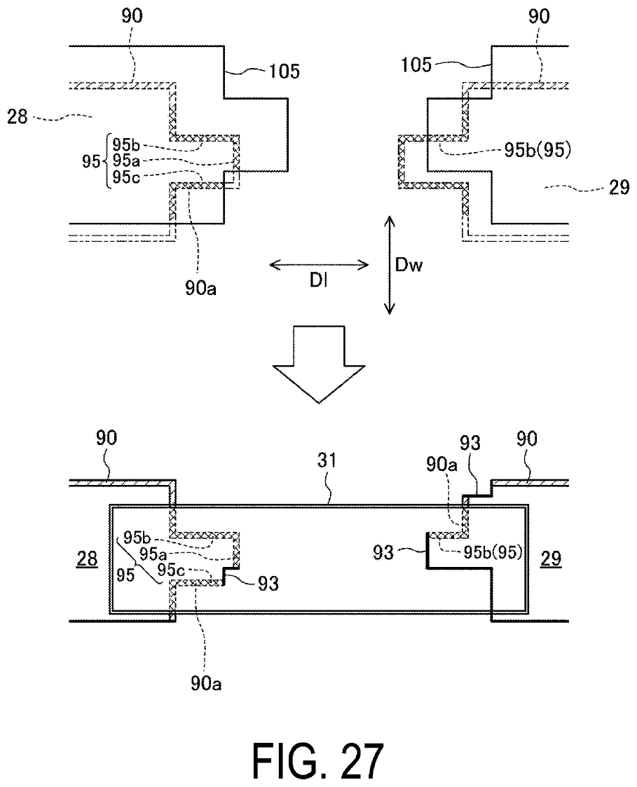

For example, as illustrated in FIG. 27, when the formation position of the second resist 105 is also shifted from the desired position to one side in the channel width direction Dw (the upper side of the paper in FIG. 27), a portion of the semiconductor layer formable inclined surface 90a of the third terminal electrode 28 and a wider portion of each inclined surface 90 of the fourth terminal electrode 29 are exposed from the second resist 105 and removed by dry etching in the rework step, thereby forming the reworked end faces 93 (indicated by thick lines in a lower diagram in FIG. 27). However, even in this case, the semiconductor layer formable inclined surfaces 90a remain in portions of the protruding portions 95 in both the third terminal electrode 28 and the fourth terminal electrode 29, so that connection between the second semiconductor layer 31 and the third terminal electrode 28 and the fourth terminal electrode 29 are ensured.

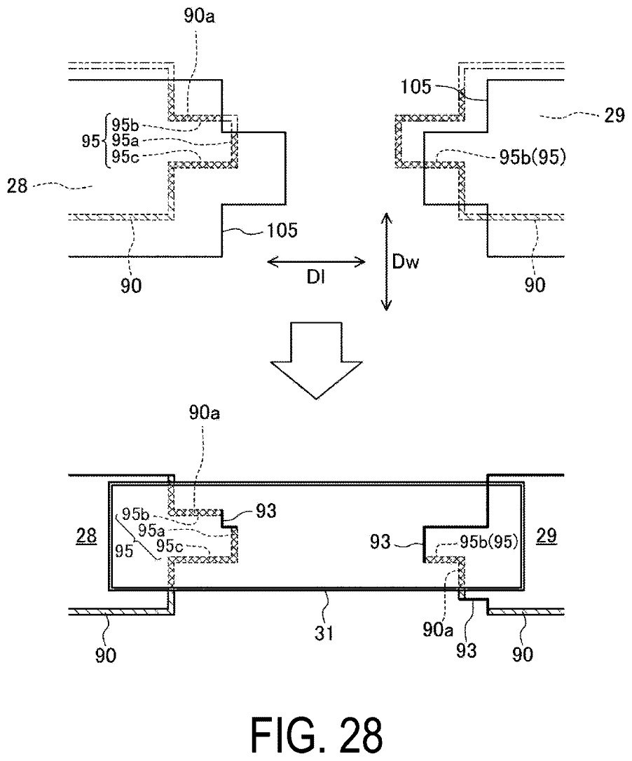

For example, as illustrated in FIG. 28, when the formation position of the second resist 105 is also shifted from the desired position to the other side in the channel width direction Dw (the lower side of the paper in FIG. 28), a portion of the semiconductor layer formable inclined surface 90a of the third terminal electrode 28 and a wider portion of each inclined surface 90 of the fourth terminal electrode 29 are exposed from the second resist 105 and are removed by dry etching in the rework step, thereby forming the reworked end faces 93 (indicated by thick lines in the lower diagram in FIG. 28). However, even in this case, the semiconductor layer formable inclined surfaces 90a remain in portions of the protruding portions 95 in the third terminal electrode 28 and the fourth terminal electrode 29, so that connection between the second semiconductor layer 31 and the third terminal electrode 28 and the fourth terminal electrode 29 are ensured.

These can also be applied when the formation position of the second resist 105 is shifted from the desired position to the other side in the channel length direction Dl (the left side of the paper in FIG. 25), specifically, when the formation position of the second resist 105 corresponding to the third terminal electrode 28 is shifted away from the fourth terminal electrode 29 and the formation position of the second resist 105 corresponding to the fourth terminal electrode 29 is shifted closer to the third terminal electrode 28, and connection between the second semiconductor layer 31 and the third terminal electrode 28 and the fourth terminal electrode 29 are ensured.

### Advantages of Second Embodiment

In the second TFT 50B according to the second embodiment, the semiconductor layer formable inclined surfaces 90a of the third terminal electrode 28 and the fourth terminal electrode 29 for the second semiconductor layer 31 form the protruding portions 95 that protrude inward in the channel length direction Dl in a plan view. According to this configuration, in the fabrication of the second TFT 50B, even when misalignment occurs in the formation position of the second resist 105 used as a mask in the rework step of removing the film residue 101r of the first metal film 101 between the third terminal electrode 28 and the fourth terminal electrode 29, portions having a good inclined surface state that are not etched can be left on the semiconductor layer formable inclined surfaces 90a of the third terminal electrode 28 and the fourth terminal electrode 29. Thus, at least part of the second semiconductor layer 31 can be provided with an appropriate thickness so as to be formed on the third terminal electrode 28 and the fourth terminal electrode 29 without interruption. This suppresses a connection failure between the second semiconductor layer 31 and both the third terminal electrode 28 and the fourth terminal electrode 29.

In the second TFT 50B according to the second embodiment, the protruding portion 95 is formed in the shape of a rectangular protrusion. The outer edge portion of such a protruding portion 95 is composed of the fifth edge portion 95b and the sixth edge portion 95c facing directions away from each other, and the fourth edge portion 95a connecting the fifth edge portion 95b and the sixth edge portion 95c at the tip of the protruding portion 95. The inclined surfaces 90 of the fourth to sixth edge portions 95a, 95b, and 95c face in directions different from each other. Thus, even when misalignment occurs in the formation position of the second resist 105 used as a mask in the rework step described above, portions having a good inclined surface state that are not dry etched in the rework step can be ensured in the inclined surfaces 90 facing at least two different directions in the outer edge portions of the protruding portions 95 in the third terminal electrode 28 and the fourth terminal electrode 29.

In the method of manufacturing the organic EL display device 1 according to the second embodiment, in the terminal electrode forming step, the outer edge portions of the third terminal electrode 28 and the fourth terminal electrode 29 are formed into the tapered inclined surfaces 90. Then, the third terminal electrode 28 and the fourth terminal electrode 29 are formed into a shape in which the semiconductor layer formable inclined surfaces 90a form the protruding portions 95 protruding inward in the channel length direction Dl in a plan view. According to this configuration, even when misalignment occurs in the formation position of the second resist 105 in the rework step, portions having a good inclined surface state that are not etched can be left on the semiconductor layer formable inclined surfaces 90a of the third terminal electrode 28 and the fourth terminal electrode 29. Thus, at least part of the second semiconductor layer 31 can be provided with an appropriate thickness so as to be formed on the third terminal electrode 28 and the fourth terminal electrode 29 without interruption. This suppresses a connection failure between the second semiconductor layer 31 and both the third terminal electrode 28 and the fourth terminal electrode 29.

### Third Embodiment

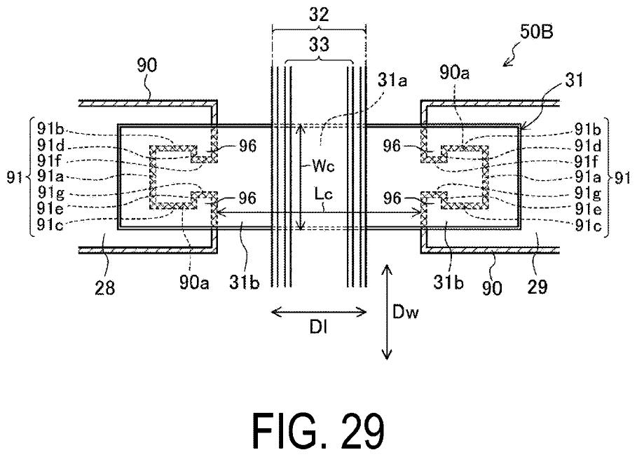

As illustrated in FIG. 29, in a second TFT 50B according to a third embodiment, a semiconductor layer formable inclined surface 90a of a third terminal electrode 28 and a semiconductor layer formable inclined surface 90a of a fourth terminal electrode 29 each form recessed portions 91 recessed outward in a channel length direction Dl in a plan view. Protruding portions 96 protruding inward from the recessed portion 91 is provided in portions on an open end side of each of the recessed portions 91 of the third terminal electrode 28 and the fourth terminal electrode 29.

Each recessed portion 91 is configured to include, in addition to first to third edge portions 91a, 91b, and 91c similar to those according to the first embodiment, a seventh edge portion 91d, an eighth edge portion 91e, a ninth edge portion 91f, and a tenth edge portion 91g.

The seventh edge portion 91d is a portion that extends inward in a channel width direction Dw from an end portion of the second edge portion 91b on a channel region 31a side and faces a back side of the recessed portion 91 in a plan view. The eighth edge portion 91e is a portion that extends inward in the channel width direction Dw from an end portion of the third edge portion 91c on the channel region 31a side and faces the back side of the recessed portion 91 in a plan view.

The ninth edge portion 91f is a portion that extends from an inner end portion of the seventh edge portion 91d in the channel width direction Dw toward the channel region 31a. The tenth edge portion 91g is a portion that extends from an inner end portion of the eighth edge portion 91e in the channel width direction Dw toward the channel region 31a. The ninth edge portion 91f and the tenth edge portion 91g face each other in the channel width direction Dw.

### Rework Step

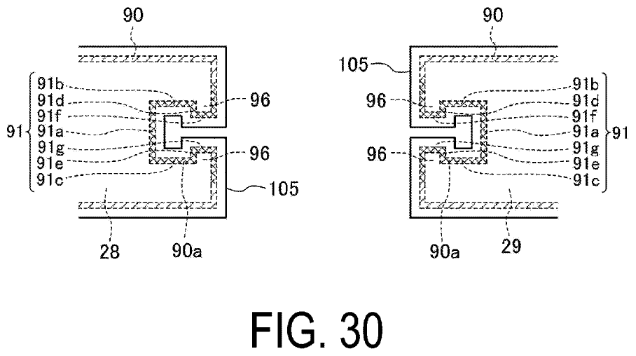

A shape of a second resist 105 formed in a rework step according to the third embodiment differs from that according to the first embodiment. As illustrated in FIG. 30, in this example, the shape of the second resist 105 corresponding to the third terminal electrode 28 is similar to the external shape of the third terminal electrode 28 but slightly larger in a plan view. The shape of the second resist 105 corresponding to the fourth terminal electrode 29 is similar to the external shape of the fourth terminal electrode 29 but slightly larger in a plan view.

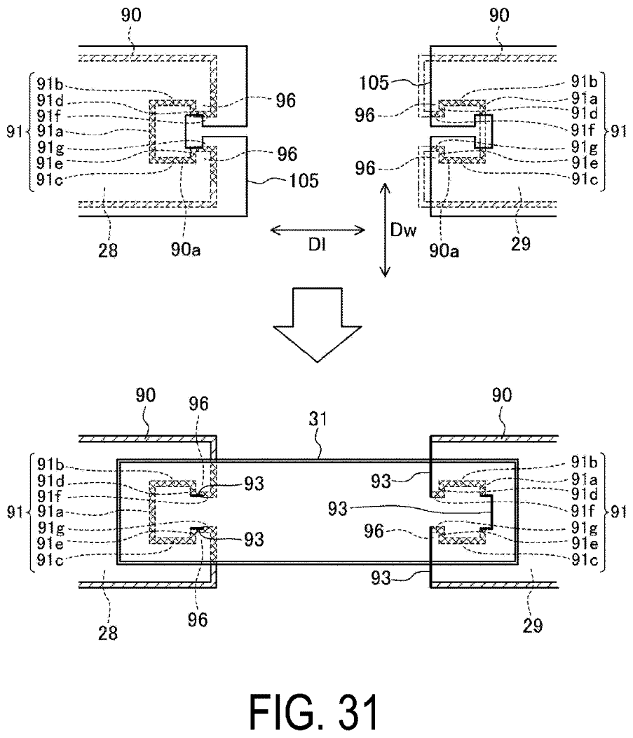

In the rework step, for example, as illustrated in FIG. 31, when a formation position of the second resist 105 is shifted from a desired position to one side in the channel length direction Dl, specifically, when the formation position of the second resist 105 corresponding to the third terminal electrode 28 is shifted closer to the fourth terminal electrode 29 and the formation position of the second resist 105 corresponding to the fourth terminal electrode 29 is shifted away from the third terminal electrode 28, a portion of the third terminal electrode 28 on the channel region 31a side and a portion of the fourth terminal electrode 29 on the channel region 31a side are exposed from the second resist 105 (a state illustrated by two-dot chain lines in FIG. 31).

When this happens, the portions of the third terminal electrode 28 and the fourth terminal electrode 29 exposed from the second resist 105, specifically, tip portions of the protruding portions of the third terminal electrode 28 and both side portions of the recessed portion 91 and part of the first edge portion 91a in the fourth terminal electrode 29 are removed by dry etching in the rework step. Reworked end faces 93 (indicated by thick lines in a lower diagram in FIG. 31) of the third terminal electrode 28 and the fourth terminal electrode 29 formed by this dry etching are formed to have a steep slope at a right angle or an approximately right angle.

When the second semiconductor layer 31 is formed so as to partially overlap the third terminal electrode 28 and the fourth terminal electrode 29 in such a state, the second semiconductor layer 31 may become extremely thin or may be discontinued and divided at the reworked end faces 93 of the third terminal electrode 28 and the fourth terminal electrode 29. However, the semiconductor layer formable inclined surfaces 90a of the third terminal electrode 28 and the fourth terminal electrode 29 remain in parts of the recessed portions 91 covered with the second resist 105.

Therefore, even when the second semiconductor layer 31 is divided at the reworked end faces 93, the second semiconductor layer 31 is continuously formed from the outside of the third terminal electrode 28 along the semiconductor layer formable inclined surface 90a of the recessed portion 91 to the top of the third terminal electrode 28, and is continuously formed from the outside of the fourth terminal electrode 29 along the semiconductor layer formable inclined surface 90a of the recessed portion 91 to the top of the fourth terminal electrode 29. Thus, connection between the second semiconductor layer 31 and the third terminal electrode 28 and the fourth terminal electrode 29 are ensured.

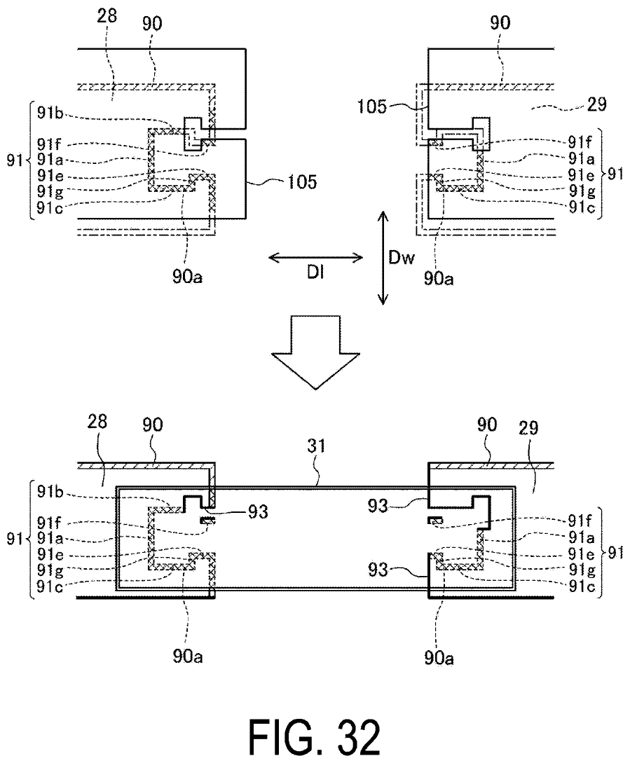

For example, as illustrated in FIG. 32, when the formation position of the second resist 105 is also shifted from the desired position to one side in the channel width direction Dw (the upper side of the paper in FIG. 32), a portion of the semiconductor layer formable inclined surface 90a of the third terminal electrode 28 and a wider portion of each inclined surface 90 of the fourth terminal electrode 29 are exposed from the second resist 105 and removed by dry etching in the rework step, thereby forming the reworked end faces 93 (indicated by thick lines in a lower diagram in FIG. 32). However, even in this case, the semiconductor layer formable inclined surfaces 90a of the recessed portions 91 remain in both the third terminal electrode 28 and the fourth terminal electrode 29, so that connection between the second semiconductor layer 31 and the third terminal electrode 28 and the fourth terminal electrode 29 are ensured.

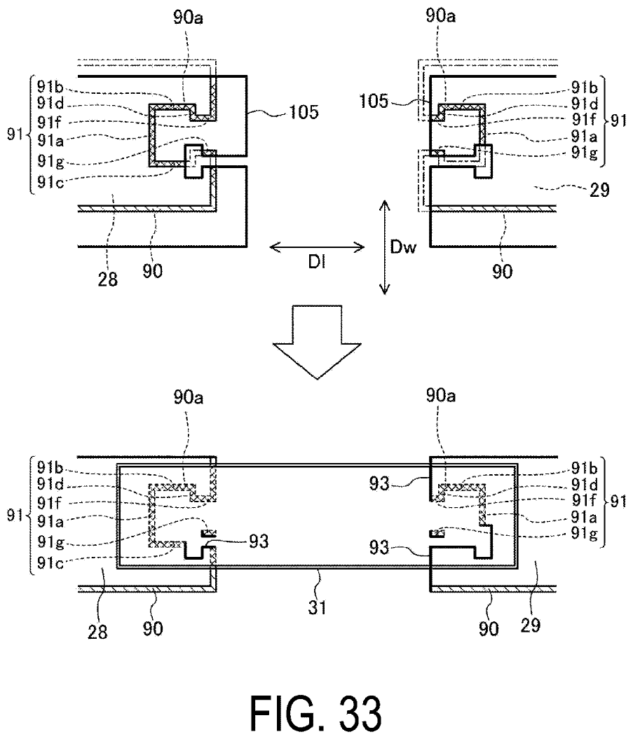

For example, as illustrated in FIG. 33, when the formation position of the second resist 105 is also shifted from the desired position to the other side in the channel width direction Dw (the lower side of the paper in FIG. 33), a portion of the semiconductor layer formable inclined surface 90a of the third terminal electrode 28 and a wider portion of each inclined surface 90 of the fourth terminal electrode 29 are exposed from the second resist 105 and are removed by dry etching in the rework step, thereby forming the reworked end faces 93 (indicated by thick lines in a lower diagram in FIG. 33). However, even in this case, the semiconductor layer formable inclined surfaces 90a of the recessed portions 91 remain in both the third terminal electrode 28 and the fourth terminal electrode 29, so that connection between the second semiconductor layer 31 and the third terminal electrode 28 and the fourth terminal electrode 29 are ensured.

These can also be applied when the formation position of the second resist 105 is shifted from the desired position to the other side in the channel length direction Dl, specifically, when the formation position of the second resist 105 corresponding to the third terminal electrode 28 is shifted away from the fourth terminal electrode 29 and the formation position of the second resist 105 corresponding to the fourth terminal electrode 29 is shifted closer to the third terminal electrode 28, and connection between the second semiconductor layer 31 and the third terminal electrode 28 and the fourth terminal electrode 29 are ensured.

### Advantages of Third Embodiment

In the second TFT 50B according to the third embodiment, the protruding portions 96 protruding inward from the recessed portion 91 are provided in portions on the open end side of each of the recessed portions 91 of the third terminal electrode 28 and the fourth terminal electrode 29. The protruding portions 96 include the seventh edge portion 91d and the eighth edge portion 91e that have inclined surfaces facing the back of the recessed portion 91 in a plan view. Thus, even when misalignment occurs in the formation position of the second resist 105 used as a mask in the rework step, portions having a good inclined surface state that are not etched can be ensured in the inclined surfaces 90 facing more directions in the recessed portions 91 of the third terminal electrode 28 and the fourth terminal electrode 29.

### OTHER EMBODIMENTS

In the first and third embodiments, the recessed portion 91 is provided in each of the third terminal electrode 28 and the fourth terminal electrode 29, but the configuration is not limited thereto. The recessed portion 91 may be provided in only one of the third terminal electrode 28 and the fourth terminal electrode 29. In short, the semiconductor layer formable inclined surface 90a of at least one of the third terminal electrode 28 and the fourth terminal electrode 29 is to form the recessed portion 91 recessed outward in the channel length direction Dl in a plan view.

In the second embodiment, the protruding portion 95 is provided in each of the third terminal electrode 28 and the fourth terminal electrode 29, but the configuration is not limited thereto. The protruding portion 95 may be provided in only one of the third terminal electrode 28 and the fourth terminal electrode 29. In short, the semiconductor layer formable inclined surface 90a of at least one of the third terminal electrode 28 and the fourth terminal electrode 29 is to form the protruding portion 95 that protrudes inward in the channel length direction Dl in a plan view.

In the first to third embodiments, the third terminal electrode 28 and the fourth terminal electrode 29 are each made of a metal material containing molybdenum (Mo) or tungsten (W), but the metal material is not limited thereto. The third terminal electrode 28 and the fourth terminal electrode 29 may be formed of any other metal material.

The third terminal electrode 28 and the fourth terminal electrode 29 are preferably made of a metal material that is resistant to hydrofluoric acid. That is, in the fabrication of the second TFT 50B, in the terminal electrode forming step, the third terminal electrode 28 and the fourth terminal electrode 29 are preferably formed of a metal material that is resistant to hydrofluoric acid. Thus, a hydrofluoric acid aqueous solution suitable for the cleaning liquid can be used in the cleaning step.

In the first to third embodiments, the organic EL display device 1 includes the first TFT 50A and the second TFT 50B, but the configuration is not limited thereto. The organic EL display device 1 may include only the second TFT 50B. For example, the pixel circuit PC may be composed of the multiple second TFTs 50B and the capacitor 55.

In the first to third embodiments, the second semiconductor layer 31 of the second TFT 50B is made of an oxide semiconductor, but the semiconductor material is not limited thereto. When the second TFT 50B is configured as a top gate type having a bottom contact structure, the second semiconductor layer 31 may be formed of a semiconductor material other than the oxide semiconductor, such as polysilicon.

In the first to third embodiments, the organic EL layer 62 is provided individually in each of the subpixels SP, but the configuration is not limited thereto. The organic EL layer 62 may be continuously provided to be common in the multiple subpixels SP. In this case, the organic EL display device 1 may include a color filter, for example, to perform color tone expression of each of the subpixels SP.

In the first to third embodiments, each of the pixels PX is constituted by the subpixels SP of three colors, but the number of the colors of the subpixels SP is not limited to three. The subpixels SP constituting each pixel PX may have four or more colors. The subpixels SP of three colors constituting each pixel PX are provided in a stripe array, but no such limitation is intended. The array of the multiple subpixels PS may be another array such as PenTile arrangement.

In the first to third embodiments, the pixel electrode 61 is an anode electrode, and the common electrode 63 is a cathode electrode, but the configuration is not limited thereto. The organic EL display device 1 may be configured such that the pixel electrode 61 functions as a cathode electrode and the common electrode 63 functions as an anode electrode. In this case, the organic EL layer 62 has an inverted layered structure.

In the first to third embodiments, the organic EL layer 62 has a five-layer structure including the hole injection layer, the hole transport layer, the light-emitting layer, the electron transport layer, and the electron injection layer, but the configuration is not limited thereto. The organic EL layer 62 may have a three-layer structure including a hole injection layer and hole transport layer, a light-emitting layer, and an electron transport layer and electron injection layer, and may employ any layered structure.

In the first to third embodiments, the substrate of the organic EL display device 1 is the substrate layer 10, but is not limited thereto. The substrate may be, for example, a plastic substrate made of PolyEthylene Terephthalate (PET) or a glass substrate, and any material can be used as long as the substrate has optical transparency.

In the first to third embodiments, the organic EL display device 1 has been exemplified as the display device according to the disclosure, but is not limited thereto. The technique of the disclosure can be applied to a display device provided with multiple light-emitting elements to be driven by a current. Examples of the display device include a display device including a Quantum-dot Light Emitting Diode (QLED), which is a light-emitting element using a quantum dot-containing layer. In addition, the technique of the disclosure is also applicable to a liquid crystal display device and a plasma display device.

As described above, the preferred embodiments are described as examples of the technique of the disclosure. However, the technique of the disclosure is not limited to the embodiments and the modified examples, and is also applicable to an embodiment in which modification, replacement, adding, omission, and the like are suitably made. It is understood by those skilled in the art that various modified examples can be made to the above embodiment without departing from the spirit of the technique of the disclosure, and such modified examples also belong to the scope of the technique of the disclosure.

### INDUSTRIAL APPLICABILITY

As described above, the technique of the disclosure is useful for a TFT, a display device, and a method of manufacturing a display device.

1: A thin film transistor comprising:
a pair of terminal electrodes provided at positions spaced apart from each other;
a semiconductor layer partially overlapping each of the pair of terminal electrodes;
a gate insulating film provided on the semiconductor layer; and
a gate electrode overlapping the semiconductor layer with the gate insulating film interposed between the gate electrode and the semiconductor layer,
wherein an outer edge portion of each of the pair of terminal electrodes is formed into a tapered inclined surface, and
in at least one of the pair of terminal electrodes, an inclined surface portion on which the semiconductor layer is formed forms a recessed portion recessed outward in a channel length direction in a plan view,
wherein a protruding portion protruding in the recessed portion is provided on an open end side of the recessed portion in each of the pair of terminal electrodes.

2: The thin film transistor according to claim 1,
wherein the recessed portion is provided in each of the pair of terminal electrodes.

3: The thin film transistor according to claim 1,
wherein the recessed portion is formed in a rectangular cutout shape.

4. (canceled)

5: The thin film transistor according to claim 1,
wherein a length of the recessed portion is 300 nm or more and 10000 nm or less, and
a width of the recessed portion is 1000 nm or more and 20000 nm or less.

6: A thin film transistor comprising:
a pair of terminal electrodes provided at positions spaced apart from each other;
a semiconductor layer partially overlapping each of the pair of terminal electrodes;
a gate insulating film provided on the semiconductor layer; and
a gate electrode overlapping the semiconductor layer with the gate insulating film interposed between the gate electrode and the semiconductor layer,
wherein an outer edge portion of each of the pair of terminal electrodes is formed into a tapered inclined surface, and
in at least one of the pair of terminal electrodes, an inclined surface portion on which the semiconductor layer is formed forms a protruding portion protruding inward in a channel length direction in a plan view,
wherein the protruding portion is provided in each of the pair of terminal electrodes,
wherein a length of the protruding portion is 500 nm or more and 10000 nm or less, and
a width of the protruding portion is 1000 nm or more and 20000 nm or less.

7. (canceled)

8: The thin film transistor according to claim 6,
wherein the protruding portion is formed in a shape of a rectangular protrusion.

9. (canceled)

10: The thin film transistor according to claim 6,
wherein the semiconductor layer is made of an oxide semiconductor.

11. (canceled)

12: The thin film transistor according to claim 6,
wherein each of the pair of terminal electrodes is made of a metal material including molybdenum, tungsten, or another metal being resistant to hydrofluoric acid.

13: A display device comprising:
the thin film transistor according to claim 6.

14-17. (canceled)

18: A method of manufacturing a display device comprising:
forming a pair of terminal electrodes at positions spaced apart from each other by depositing a conductive film on a substrate and forming a first resist on the conductive film at locations where the pair of terminal electrodes are to be formed, and then patterning the conductive film by etching using the first resist as a mask, and removing the first resist;
after forming a second resist covering the pair of terminal electrodes and removing a film residue of the conductive film by etching using the second resist as a mask, removing the second resist;
forming a semiconductor layer partially overlapping each of the pair of terminal electrodes;
forming a gate insulating film on the semiconductor layer; and
forming a gate electrode on the gate insulating film,
wherein the display device includes multiple thin film transistors, each of the multiple thin film transistors including the pair of terminal electrodes, the semiconductor layer, the gate insulating film, and the gate electrode, and
in the forming a pair of terminal electrodes, an outer edge portion of each of the pair of terminal electrodes is formed into a tapered inclined surface, and at least one of the pair of terminal electrodes is formed in a shape in which an inclined surface portion on which the semiconductor layer is to be formed forms a recessed portion recessed outward in a channel length direction or a protruding portion protruding inward in the channel length direction in a plan view.

19: The method of manufacturing a display device according to claim 18, further comprising:
forming an interlayer insulating film covering the multiple thin film transistors;
forming a contact hole in the interlayer insulating film, the contact hole exposing a conductive layer forming the pair of terminal electrodes at a bottom of the contact hole;
performing a cleaning process in which the inside of the contact hole in the interlayer insulating film is cleaned with a cleaning liquid; and
forming a wiring line on the interlayer insulating film, the wiring line being electrically connected to one of the pair of terminal electrodes via the contact hole,
wherein in the forming a semiconductor layer, the semiconductor layer is formed of an oxide semiconductor.

20: The method of manufacturing a display device according to claim 19,
wherein in the forming a pair of terminal electrodes, the pair of terminal electrodes are formed of a metal material containing molybdenum, tungsten, or another metal being resistant to hydrofluoric acid, and
in the performing a cleaning process, a hydrofluoric acid solution is used as the cleaning liquid.

21: The thin film transistor according to claim 1,
wherein the semiconductor layer is made of an oxide semiconductor.

22: The thin film transistor according to claim 21,
wherein the oxide semiconductor includes at least one semiconductor selected from the group consisting of an In—Ga—Zn—O based semiconductor, an In—Sn—Zn—O based semiconductor, an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, and an In—Ga—Zn—Sn—O based semiconductor.

23: The thin film transistor according to claim 1,
wherein each of the pair of terminal electrodes is made of a metal material including molybdenum, tungsten, or another metal being resistant to hydrofluoric acid.

24: A display device comprising:
the thin film transistor according to claim 1.

25: The display device according to claim 24, comprising:
a substrate; and
a thin film transistor layer provided on the substrate,
wherein the thin film transistor layer includes multiple thin film transistors, each of the multiple thin film transistors corresponding to multiple subpixels forming a display region.

26: The display device according to claim 25,
wherein the thin film transistor layer includes first thin film transistors, each of the first thin film transistors including a semiconductor layer made of polysilicon, and second thin film transistors, each of the second thin film transistors including a semiconductor layer made of an oxide semiconductor, and
each of the second thin film transistors is the thin film transistor.

27: The display device according to claim 26, further comprising:
a light-emitting element layer provided on the thin film transistor layer,
wherein the light-emitting element layer includes light-emitting elements corresponding to the multiple subpixels, and
each of the first thin film transistors and each of the second thin film transistors constitute a pixel circuit configured to control light emission of each of the light-emitting elements.

28: The display device according to claim 27,
wherein the light-emitting elements are organic electroluminescence elements.
